(19) United States
(12) Patent Application Publication
(10) Pub. No.: US 2026/0135357 A1
(43) Pub. Date: May 14, 2026

(54) FASTENING MEMBER AND ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Kazuhiko Tsuchiya, Kakegawa-shi (JP)

(21) Appl. No.: 19/347,773

(22) Filed: Oct. 2, 2025

(30) Foreign Application Priority Data
Oct. 7, 2024 (JP) 2024-175909

(51) Int. Cl. H02B 1/56; H02B 1/01; H05K 7/20

(52) U.S. Cl. CPC H02B 1/56; H02B 1/012; H05K 7/20418; H05K 7/20509

(57) ABSTRACT

A fastening member of an electrical connection unit includes a shaft, a base portion, and a heat storage portion. The shaft is inserted into a first attachment hole of a first member and a second attachment hole of a second member in a state in which the first attachment hole and the second attachment hole overlap each other in a first direction. The shaft has a screw thread. When a direction intersecting the first direction is a second direction, a width of the base portion in the second direction is larger than a width of the shaft. The base portion faces the first member or the second member in the first direction. The heat storage portion is provided on a side opposite to the shaft with respect to the base portion. The heat storage portion is formed integrally with the base portion.

### TECHNICAL FIELD

Embodiments of the present invention relate to a fastening member and an electrical connection unit.

Priority is claimed on Japanese Patent Application No. 2024-175909 filed in Japan on Oct. 7, 2024, the content of which is incorporated herein by reference.

### BACKGROUND ART

An electrical connection unit having an electronic component and a bus bar electrically connected to the electronic component is known.

### PRIOR ART DOCUMENT

### Patent Document

[Patent Document 1]: Japanese Unexamined Patent Application, First Publication No. 2024-037492

### SUMMARY OF THE INVENTION

### Problems to be Solved by the Invention

Incidentally, it is expected to improve thermal characteristics of an electrical connection unit.

An embodiment provides a fastening member and an electrical connection unit capable of improving thermal characteristics.

### Means for Solving the Problem

A fastening member of one embodiment is used in an electrical connection unit. The fastening member includes a shaft, a base portion, and a heat storage portion. The shaft is inserted into a first attachment hole of a first member and a second attachment hole of a second member in a state in which the first attachment hole and the second attachment hole overlap each other in a first direction. The shaft has a screw thread. When a direction intersecting the first direction is a second direction, a width of the base portion in the second direction is larger than a width of the shaft. The base portion faces the first member or the second member in the first direction. The heat storage portion is provided on a side opposite to the shaft with respect to the base portion. The heat storage portion is formed integrally with the base portion.

An electrical connection unit according to an embodiment includes at least one of a first member and a second member, and a fastening member. The fastening member includes a shaft, a base portion, and a heat storage portion. The shaft is inserted into a first attachment hole of a first member and a second attachment hole of a second member in a state in which the first attachment hole and the second attachment hole overlap each other in a first direction. The shaft has a screw thread. When a direction intersecting the first direction is a second direction, a width of the base portion in the second direction is larger than a width of the shaft. The base portion faces the first member or the second member in the first direction. The heat storage portion is provided on a side opposite to the shaft with respect to the base portion. The heat storage portion is formed integrally with the base portion.

A fastening member of one embodiment is used in an electrical connection unit. The fastening member includes a first portion and a second portion. The first portion is inserted into a first attachment hole of a first member and a second attachment hole of a second member in a state in which the first attachment hole and the second attachment hole overlap each other in a first direction. The first portion has a screw thread and is engaged with a nut. When a direction intersecting the first direction is a second direction, a width of the second portion in the second direction is larger than a width of the first portion. The second portion faces the first member or the second member in the first direction. The second portion has a volume twice or more the volume of the nut.

An electrical connection unit according to an embodiment includes at least one of a first member and a second member, and a fastening member. The fastening member includes a first portion and a second portion. The first portion is inserted into a first attachment hole of a first member and a second attachment hole of a second member in a state in which the first attachment hole and the second attachment hole overlap each other in a first direction. The first portion has a screw thread and is engaged with a nut. In a case where a direction intersecting the first direction is a second direction, a width of the second portion in the second direction is larger than a width of the first portion. The second portion faces the first member or the second member in the first direction. The second portion has a volume twice or more the volume of the nut.

An electrical connection unit according to an embodiment includes a fastening member, a heat dissipation member, and a heat transfer member. The fastening member includes a first portion and a second portion. The first portion is inserted into a first attachment hole of a first member and a second attachment hole of a second member in a state in which the first attachment hole and the second attachment hole overlap each other in a first direction. The first portion has a screw thread. When a direction intersecting the first direction is a second direction, a width of the second portion in the second direction is larger than the first. The second portion faces the first member or the second member in the first direction. The heat dissipation member faces the second portion from a side opposite to the first member and the second member. The heat transfer member is disposed between the second portion and the heat dissipation member.

### Effects of Invention

According to one embodiment, it is possible to improve thermal characteristics.

### BRIEF DESCRIPTION OF THE DRAWINGS

FIG. 1 A cross-sectional view illustrating an electrical connection unit of a first embodiment.

FIG. 2 A perspective view showing a main body of the first embodiment.

FIG. 3 A perspective view showing one subunit of the first embodiment.

FIG. 4 A perspective view illustrating an electronic component and a connection component of the first embodiment.

FIG. 5 A perspective view showing a routing board of the first embodiment.

FIG. 6 A partially exploded perspective view of the routing board of the first embodiment.

FIG. 7 A cross-sectional view taken along line F7-F7 of a structure illustrated in FIG. 3.

FIG. 8 A cross-sectional view taken along line F8-F8 of the structure illustrated in FIG. 3.

FIG. 9 A perspective view illustrating another subunit of the first embodiment.

FIG. 10 A front view illustrating an electronic component of the first embodiment.

FIG. 11 A perspective view illustrating a base member of the first embodiment.

FIG. 12 A plan view illustrating a subunit of the first embodiment.

FIG. 13 A cross-sectional view taken along line F13-F13 of a structure illustrated in FIG. 12.

FIG. 14 A perspective view showing a fastening member of the first embodiment.

FIG. 15 A cross-sectional view taken along line F15-F15 of the structure illustrated in FIG. 12.

FIG. 16 A cross-sectional view illustrating a subunit of a modification example of the first embodiment.

FIG. 17 A perspective view illustrating a fastening member of a modification example of the first embodiment.

FIG. 18 A partially exploded perspective view illustrating a subunit of a second embodiment.

FIG. 19 A perspective view illustrating a part of a subunit of a third embodiment.

FIG. 20 A partially exploded perspective view illustrating a subunit of the third embodiment.

FIG. 21 A cross-sectional view illustrating the subunit of the third embodiment.

FIG. 22 A cross-sectional view illustrating a subunit of a fourth embodiment.

### EMBODIMENTS FOR CARRYING OUT THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively.

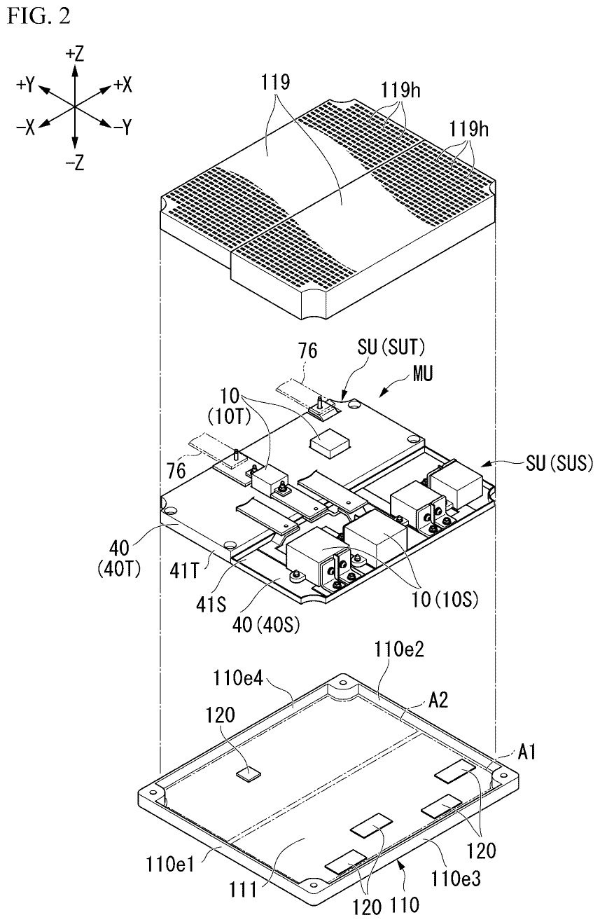

In the present disclosure, a +X direction, a −X direction, a +Y direction, a −Y direction, a +Z direction, and a −Z direction are defined as follows. The +X direction is a direction from a first end 110e1 to a second end 110e2 of a metal plate 110 that will be described later (see FIG. 2). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 110e3 to a fourth end 110e4 of the metal plate 110 that will be described later (see FIG. 2). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 110 that will be described later toward a main body MU (see FIG. 2). The −Z direction is a direction opposite to the +Z direction. Hereinafter, in a case where the +Z direction and the −Z direction are not distinguished, the directions will be simply referred to as “Z direction”. The Z direction is an example of a “first direction”. One of the X direction and the Y direction is an example of a “second direction”. The other of the X direction and the Y direction is an example of a “third direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### First Embodiment

### 1. Constitution of Electrical Connection Unit

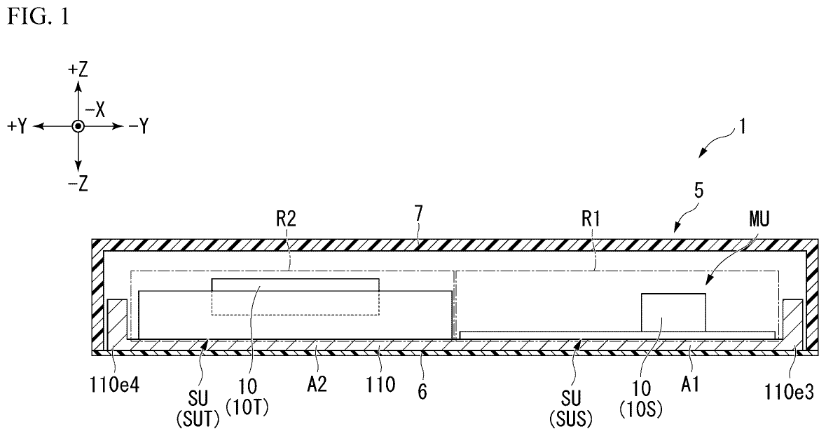

FIG. 1 is a cross-sectional view illustrating an electrical connection unit 1 of an embodiment. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device.

The electrical connection unit 1 includes, for example, a casing 5, a main body MU, a metal plate 110, a plurality of insulating covers 119 (see FIG. 2), and a plurality of heat transfer members 120 (see FIG. 2).

### 2. Casing

First, the casing 5 will be described. The casing 5 forms an outline of the electrical connection unit 1. The casing 5 includes, for example, a base 6 and a cover 7. The base 6 is a member that covers the main body MU and the metal plate 110 from below. The base 6 has, for example, a plate shape formed in the horizontal direction or a bowl shape open in the +Z direction. The base 6 is made of, for example, a synthetic resin. The cover 7 is a member that covers the main body MU and the metal plate 110 from above. The base 6 has, for example, a bowl shape open in the −Z direction. The cover 7 is made of, for example, a synthetic resin. In the present embodiment, the box-shaped casing 5 is formed by combining the base 6 and the cover 7. The shape of the casing 5 is not limited to the above example. For example, the metal plate 110 that will be described later may function as a part or the whole of the base 6. The casing 5 may be omitted.

In the present embodiment, the electrical connection unit 1 includes a first region (first space) R1 and a second region (second space) R2. The first region R1 is a region in which a heat dissipation property is emphasized. In the first region R1, for example, an electronic component 10S having a great amount of heat generation is disposed. On the other hand, the second region R2 is a region in which a mountability is emphasized. In the second region R2, for example, an electronic component 10T that has a smaller amount of heat generation than the electronic component 10S and/or requires a more complicated mounting structure than the electronic component 10S is disposed. However, these contents do not limit the contents of the electrical connection unit 1 of the present disclosure. For example, the amount of heat generation of the electronic component 10T may be greater than the amount of heat generation of the electronic component 10S.

### 3. Main Body

Next, the main body MU will be described.

FIG. 2 is a perspective view showing the main body MU. The main body MU is a portion that performs a main function (for example, switching of electrical connection states or overcurrent protection) of the electrical connection unit 1. In the present embodiment, the main body MU is divided into a plurality of subunits SU. The main body MU is formed by connecting the plurality of subunits SU, for example. In the present embodiment, the main body MU includes two subunits SU (subunit SUS and SUT). Each subunit SU may be referred to as a “circuit constitution body”.

The subunit SUS has an electrical first function. The subunit SUS includes, for example, a plurality of electronic components 10S and a routing board 40S. The plurality of electronic components 10S are electrically connected to the routing board 40S. The base plate 41S (that will be described later) included in the subunit SUS is an example of a “first base member”.

The subunit SUT has an electrical second function. The second function is, for example, a function different from the first function. The subunit SUT includes, for example, a plurality of electronic components 10T and a routing structure 40T. The plurality of electronic components 10T are electrically connected to the routing structure 40T. The base member 41T (that will be described later) included in the subunit SUT is an example of a “second base member”.

In the present embodiment, the subunit SUS is a subunit SU in which a heat dissipation property is emphasized. The subunit SUS is disposed in the above first region R1 of the electrical connection unit 1. The subunit SUS faces a first region Al of the metal plate 110 that will be described later in the Z direction.

On the other hand, the subunit SUT is a subunit SU in which the mountability is emphasized. The subunit SUT is disposed, for example, on the +Y direction side with respect to the subunit SUS. The subunit SUT is disposed in the above second region R2 of the electrical connection unit 1. The subunit SUT faces a second region A2 of the metal plate 110 that will be described later in the Z direction. Hereinafter, in a case where the electronic component 10S and the electronic component 10T are not distinguished, the electronic components are simply referred to as “electronic component 10”.

Note that the main body MU need not be divided into a plurality of subunits SU instead of the example described above. For example, the plurality of subunits SU may be integrally formed. For example, a base plate 41S of the routing board 40S and a base member 41T of the routing structure 40T, which will be described later, may be integrally formed by one piece member.

### 4. Constitution of Subunit SUS

Next, a constitution of the subunit SUS will be described.

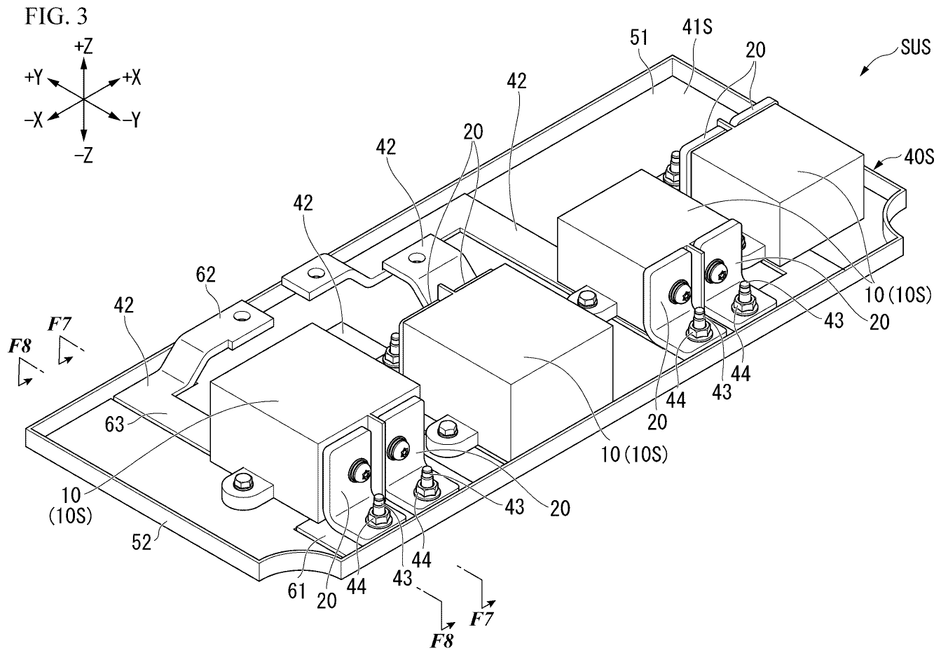

FIG. 3 is a perspective view showing the subunit SUS. The subunit SUS includes, for example, a plurality of electronic components 10, a plurality of connection components 20, and a routing board 40S. The connection component 20 is a member forming an energization path in the vertical direction. The connection component 20 may be referred to as a “vertical routing member”.

### <4.1 Electronic Component>

First, the electronic component 10 will be described. The electronic component 10 is an electronic component mounted according to a function required for each subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. However, the type of the electronic component 10 is not limited to the above example. The electronic component 10 is, for example, a heat generating component that generates heat at the time of energization.

In the present embodiment, the plurality of electronic components 10 include an electronic component 10S that generates relatively large heat when energized. The electronic component 10S is a relay (for example, a mechanical relay or a semiconductor relay), a pyrofuse, a current sensor (for example, a current sensor having a shunt resistor), or the like. However, the type of the electronic component 10S is not limited to the above example.

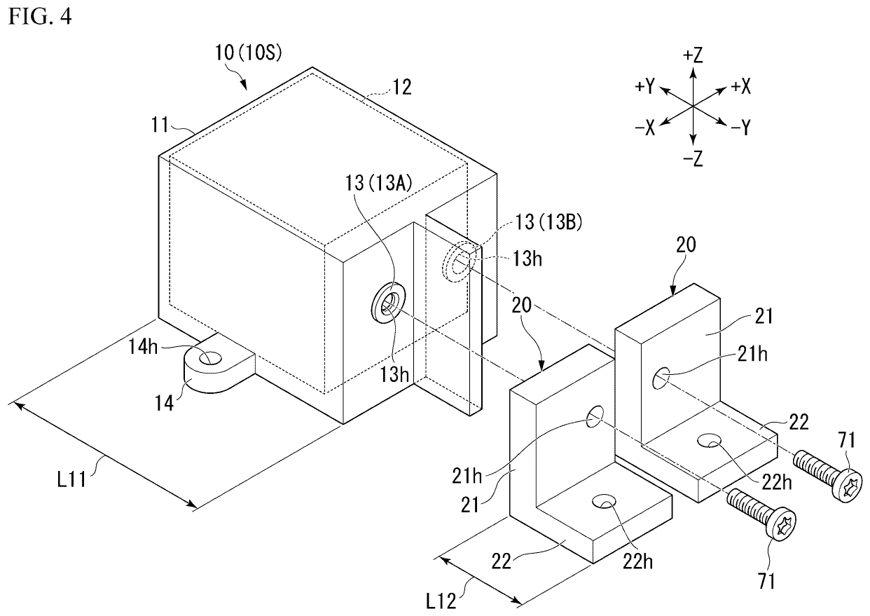

FIG. 4 is a perspective view illustrating the electronic component 10 and the connection component 20. The electronic component 10 is, for example, an electronic component in which a plurality of terminals 13 are disposed to be arranged at one end of the electronic component 10. The electronic component 10 includes, for example, a case 11, a component body 12, a plurality of terminals 13, and a plurality of the attachment portions 14.

### (Case)

The case 11 is an outer member that forms most of the outer shape of the electronic component 10. The case 11 is made of, for example, synthetic resin and has an insulating property. The case 11 accommodates the component body 12. The case 11 and the component body 12 may be integrally formed.

### (Component Body)

The component body 12 is a portion that performs a main function of the electronic component 10. For example, in a case where the electronic component 10 is a relay, the component body 12 includes a switch (for example, a contact) that switches between a conductive state and a non-conductive state. For example, in a case where the electronic component 10 is a fuse, the component body 12 includes a fusion portion that is fused when an overcurrent flows. For example, in a case where the electronic component 10 is a capacitor, the component body 12 includes a portion that stores electric charge.

### (Terminal)

The terminal 13 is an electrical connection portion exposed to the outside of the case 11. The terminal 13 is electrically connected to the component body 12 inside the case 11. In the present embodiment, the electronic component 10 includes a terminal 13A and a terminal 13B as the plurality of terminals 13. One of the terminal 13A and the terminal 13B is a terminal on the positive electrode side. The other of the terminal 13A and the terminal 13B is a terminal on the negative electrode side. One of the terminal 13A and the terminal 13B is an example of a “first terminal”. The other of the terminal 13A and the terminal 13B is an example of a “second terminal”.

In the present embodiment, the terminal 13A and the terminal 13B are provided at one end of the electronic component 10 in the horizontal direction (for example, the Y direction). The terminal 13A and the terminal 13B are disposed to be arranged in the horizontal direction (for example, the X direction). Each of the terminal 13A and the terminal 13B is directed in the horizontal direction (for example, the Y direction). Each terminal 13 has an attachment hole 13h to which a fastening member 71 (for example, a screw or a bolt) that will be described later is attached. The attachment hole 13h is open in the horizontal direction (for example, the Y direction). An inner circumferential surface of the attachment hole 13h of the electronic component 10 has a screw groove. In the present disclosure, the “attachment hole” is not limited to a hole having a screw groove, and may be a hole not having a screw groove. In the present disclosure, the “attachment hole” is not limited to a bottomed hole, and may be a through-hole.

### (Attachment Portion)

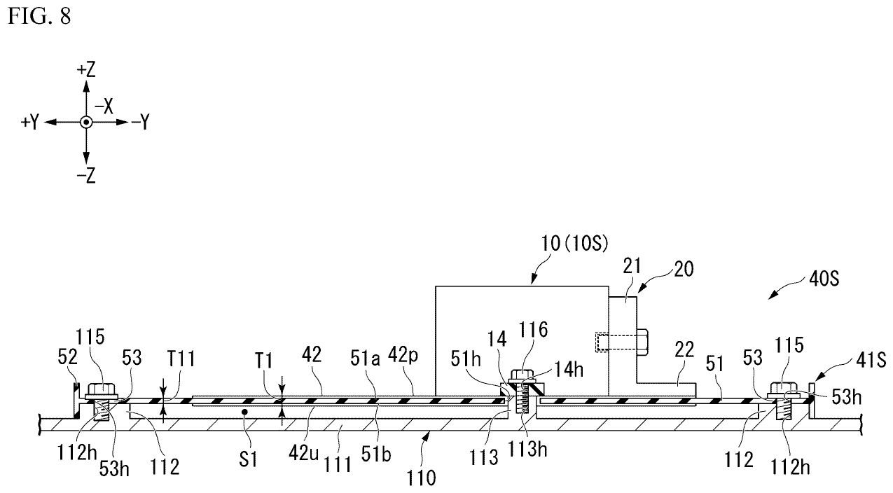

The attachment portion 14 is a portion for fixing the electronic component 10. The attachment portion 14 has an attachment hole 14h to which a fastening member 116 (for example, a screw or a bolt; and see FIG. 8) that will be described later is attached. The attachment hole 14h is open in the Z direction. The attachment hole 14h is an insertion hole through which the fastening member 116 passes. A fixing destination of the attachment portion 14 will be described later.

### <4.2 Connection Component>

Next, the connection component 20 will be described. The connection component 20 is a component that electrically connects the electronic component 10 to the routing board 40S. The connection component 20 forms a part of an energization path in the subunit SUS. The connection component 20 is made of metal (for example, made of copper, made of a copper alloy, made of aluminum, or made of an aluminum alloy). The connection component 20 may be referred to as a “metal component”.

In the present embodiment, the connection component 20 electrically connects the electronic component 10 to the bus bar 42 (see FIG. 3) included in the routing board 40S. In the present embodiment, a length L12 of the connection component 20 in the longitudinal direction (for example, the Y direction) of the electronic component 10 is smaller than a length L11 of the electronic component 10 in the longitudinal direction.

The connection component 20 includes, for example, a first portion 21 and a second portion 22.

### (First Portion)

The first portion 21 of the connection component 20 is a portion connected to the terminal 13 of the electronic component 10S. The first portion 21 is a plate-shaped or rectangular parallelepiped portion extending in the Z direction. The first portion 21 extends in the Z direction along one end (for example, an end in the Y direction) of the electronic component 10. The first portion 21 is a standing portion that stands in the Z direction with respect to the routing board 40S (for example, with respect to a bus bar 42 that will be described later). The first portion 21 is adjacent to the electronic component 10 in the horizontal direction (for example, the Y direction). For example, the first portion 21 is adjacent to the terminal 13 of the electronic component 10 in the horizontal direction (for example, the Y direction), and is connected to the terminal 13 of the electronic component 10 from the horizontal direction (for example, the Y direction).

The first portion 21 of the connection component 20 has a first attachment hole 21h through which the fastening member 71 (for example, a screw or a bolt) passes. The first attachment hole 21h is open in the horizontal direction (for example, the Y direction). The fastening member 71 that has passed through the first attachment hole 21h is engaged with the attachment hole 13h of the terminal 13 of the electronic component 10, and thus the first portion 21 is physically and electrically connected to the terminal 13 of the electronic component 10.

### (Second Portion)

The second portion 22 of the connection component 20 is a portion connected to the bus bar 42 (see FIG. 3). The second portion 22 protrudes in the horizontal direction (for example, the Y direction) from the end of the first portion 21 on the −Z direction side. The second portion 22 is a plate portion provided in the horizontal direction. The second portion 22 is adjacent to the bus bar 42 in the Z direction, and is connected to the bus bar 42 from the Z direction. The second portion 22 of the connection component 20 is attached to the fastening member 43 (for example, a screw or a bolt; and see FIG. 8) protruding from the bus bar 42 in the +Z direction from the Z direction, and is physically and electrically connected to the bus bar 42. In the present embodiment, the second portion 22 of the connection component 20 has a second attachment hole 22h through which the fastening member 43 passes. The second attachment hole 22h is open in the Z direction. In the second portion 22, the fastening member 43 passes through the second attachment hole 22h. An engagement member 44 (for example, a nut; and see FIG. 3) is engaged with the tip of the fastening member 43 that has passed through the second attachment hole 22h, and thus the second portion 22 is fixed to the bus bar 42. In the present embodiment, the first portion 21 and the second portion 22 form one L-shaped connection component 20.

In the present embodiment, the bus bar 42 is disposed at a position away from the terminal 13 of the electronic component 10 (for example, a position away in the Z direction). The connection component 20 is disposed between the electronic component 10 and the bus bar 42. In the present disclosure, the phrase “the connection component is disposed between the electronic component and the bus bar” is not limited to a case where a part of the connection component is located between the electronic component and the bus bar when viewed from the X direction or the Y direction. The phrase “the connection component is disposed between the electronic component and the bus bar” may correspond to a case where a part of the connection component is located between the electronic component and the bus bar when viewed from a direction inclined with respect to the X direction or the Y direction. The connection component 20 electrically connects the terminal 13 of the electronic component 10 to the bus bar 42.

### <4.3 Routing Board>

Next, the routing board 40S will be described.

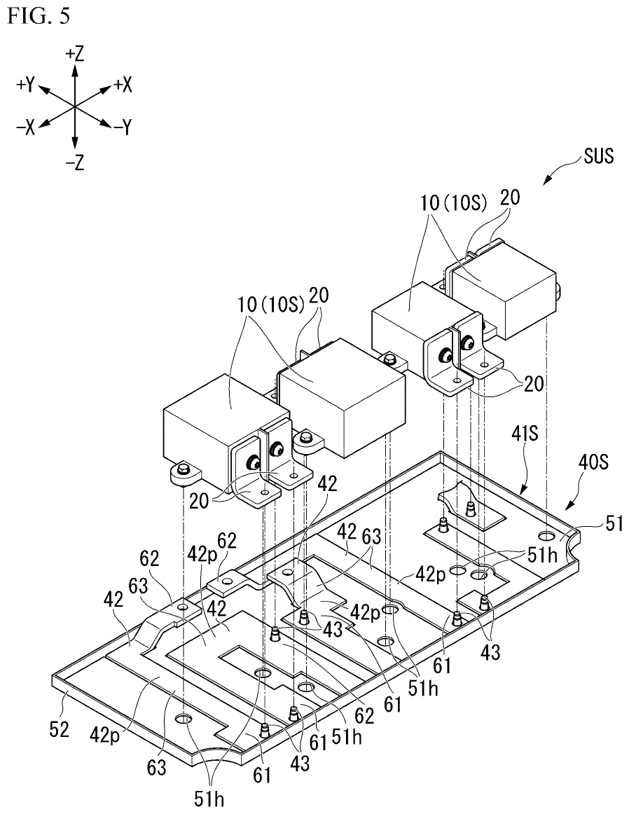

FIG. 5 is a perspective view showing the routing board 40S. The routing board 40S is a member that forms at least a part of an energization path between a plurality of electronic components 10 (for example, a plurality of electronic components 10S) and/or at least a part of an energization path between the electronic component 10 (for example, the electronic component 10S) included in the subunit SUS and the electronic component 10 included in another subunit SU (for example, the subunit SUT). In the present disclosure, the “routing board” indicates a board-type routing structure. The “board type” indicates a plate shape along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following the thickness of the bus bar is present on the surface, and the like. In the present embodiment, the routing board 40S has a plate shape formed in the X direction and the Y direction.

The routing board 40S includes, for example, a base plate 41S, one or more (for example, a plurality of) bus bars 42, and a plurality of fastening members 43. In the present embodiment, the base plate 41S and the plurality of bus bars 42 are integrated through insert molding. For example, the routing board 40S is formed as one piece member by insert-molding the bus bar 42 with the base plate 41S after the fastening member 43 is fixed to the bus bar 42. That is, the bus bar 42 is integrated with the base plate 41S without using a fastening member such as a screw or a bolt. Note that the routing board 40S may be formed by using another structure instead of the insert molding.

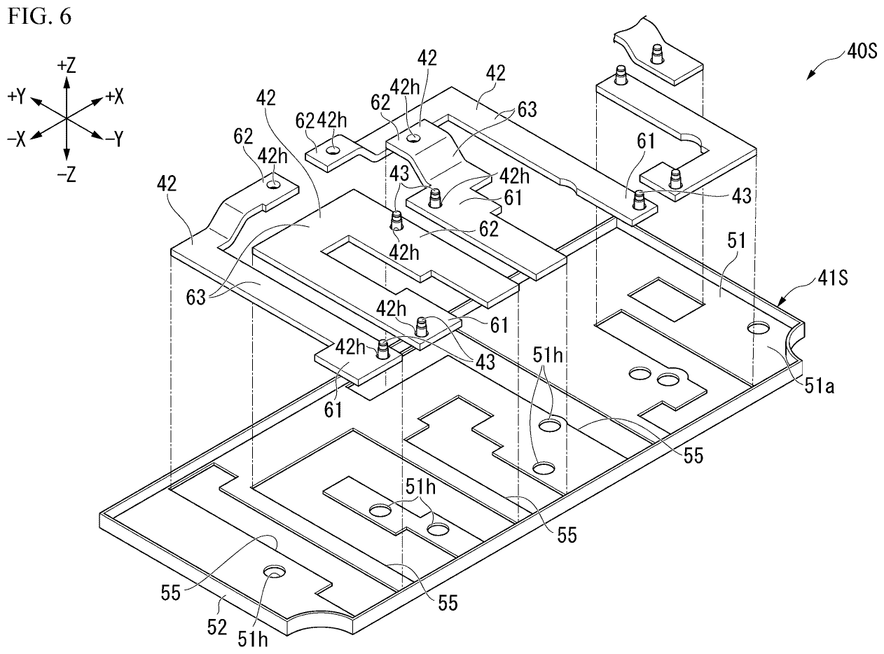

FIG. 6 is a partially exploded perspective view illustrating the routing board 40S. Hereinafter, for convenience of description, the base plate 41S, the bus bar 42, and the fastening member 43 will be described with reference to the drawings in which the routing board 40S is partially exploded.

### <4.3.1 Base Plate>

The base plate 41S is a support member that integrally supports the plurality of bus bars 42 arranged at intervals in the horizontal direction. The base plate 41S is made of, for example, a synthetic resin and has an insulating property. The base plate 41S electrically insulates the plurality of bus bars 42 from each other. The base plate 41S is an example of a “base member”. The base plate 41S may be referred to as an “insulating substrate”. The base plate 41S includes, for example, a flat surface portion 51, a frame portion 52, and a plurality of fixing portions 53 (see FIG. 8).

### (Flat Surface Portion)

The flat surface portion 51 is a portion formed in a plate shape in the base plate 41S. The flat surface portion 51 has a plate shape formed in the horizontal direction. The flat surface portion 51 forms a main portion of the base plate 41S. The flat surface portion 51 forms a base portion (insulating base portion) of the base plate 41S. In the present embodiment, the flat surface portion 51 extends over the entire width in the X direction of the base plate 41S and over the entire width in the Y direction of the base plate 41S except for the frame portion 52 of the base plate 41S.

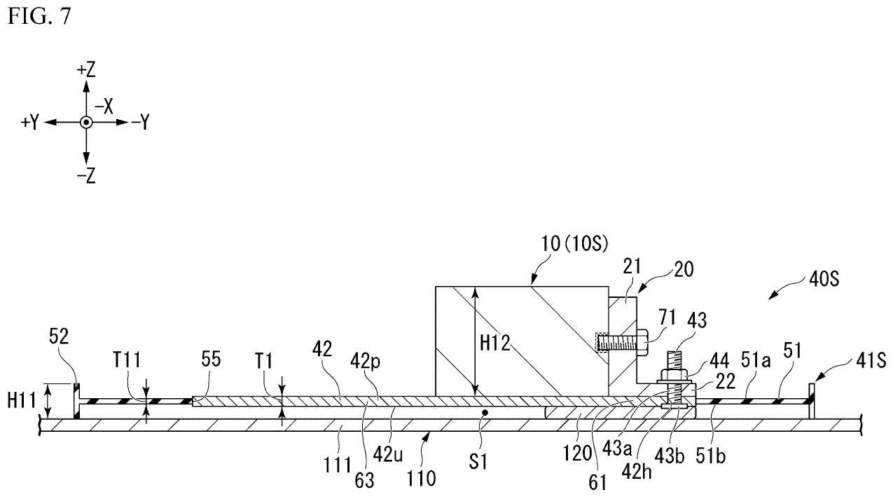

The flat surface portion 51 has a first surface 51a and a second surface 51b (see FIG. 7). The first surface 51a is a surface directed in the +Z direction. The first surface 51a is a flat surface provided in the horizontal direction. The first surface 51a faces the plurality of electronic components 10 (for example, the plurality of electronic components 10S). The second surface 51b is located on the side opposite to the first surface 51a. The second surface 51b is a surface directed in the−Z direction. The second surface 51b is a flat surface provided in the horizontal direction. The second surface 51b faces the metal plate 110 (see FIG. 2). A thickness direction (plate thickness direction) of the flat surface portion 51 is the Z direction. In the present embodiment, a thickness T11 of the flat surface portion 51 in the Z direction is smaller than a thickness T1 of the bus bar 42 in the Z direction (for example, a thickness of a horizontal plate portion 42p that will be described later in the Z direction) (see FIG. 7). The thickness T11 of the flat surface portion 51 in the Z direction may be equal to the thickness T1 of the bus bar 42 in the Z direction, or may be larger than the thickness T1 of the bus bar 42 in the Z direction.

The flat surface portion 51 has, for example, one or more (for example, a plurality of) accommodation portions 55 in which the bus bars 42 are accommodated, respectively. The plurality of accommodation portions 55 are formed apart from each other in the X direction or the Y direction. Each of the accommodation portions 55 is, for example, a through-hole penetrating the flat surface portion 51 in the Z direction. Note that the accommodation portion 55 may be a recess provided on the first surface 51a or the second surface 51b of the flat surface portion 51 and recessed in the Z direction, instead of a through-hole. In the present disclosure, the phrase “the accommodation portion penetrates the flat surface portion in the first direction (Z direction)” may include a case where a part of the entire length of the accommodation portion 55 penetrates the flat surface portion 51 in the Z direction (for example, the remaining portion of the accommodation portion 55 may be a recess recessed in the Z direction, or may be provided inside the base plate 41S and not exposed to the outside of the base plate 41S). Similarly, in the present disclosure, the phrase “the accommodation portion is recessed in the first direction (Z direction)” may include a case where a part of the entire length of the accommodation portion 55 is recessed in the Z direction (for example, a remaining portion of the accommodation portion 55 may be a through-hole penetrating the flat surface portion 51 in the Z direction, or may be provided inside the base plate 41S and not exposed to the outside of the base plate 41S). Each accommodation portion 55 has an outer shape corresponding to the shape of the bus bar 42 to be accommodated when viewed from the Z direction.

### (Frame Portion)

The frame portion 52 is provided at a peripheral end of the base plate 41S. The frame portion 52 is a reinforcement rib protruding vertically from the end of the flat surface portion 51 (see FIG. 7). A width (thickness) H11 of the frame portion 52 in the Z direction is, for example, less than half of a width (thickness) H12 of the electronic component 10 in the Z direction (see FIG. 7). Note that the frame portion 52 may be omitted.

### (Fixing Portion)

The fixing portion 53 is a portion fixed to the metal plate 110 (see FIG. 8). The fixing portion 53 has an attachment hole 53h penetrating the base plate 41S in the Z direction. A fastening member 115 (for example, a screw or a bolt) that will be described later passes through the attachment hole 53h. This content will be described later.

### <4.3.2 Bus Bar>

The bus bar 42 is a routing member (electrical connection member) included in the routing board 40S. The bus bar 42 is, for example, a routing member for electrically connecting a plurality of electronic components (for example, a plurality of electronic components 10S). Alternatively, the bus bar 42 may be a routing member for electrically connecting the electronic component 10 (for example, the electronic component 10S) to the electronic component 10 included in another subunit SU (for example, the subunit SUT). The bus bar 42 is made of metal (for example, made of copper, made of a copper alloy, made of aluminum, or made of an aluminum alloy) and has conductivity.

At least a part of each bus bar 42 has a plate shape formed in the horizontal direction. At least a part of each bus bar 42 is accommodated in the accommodation portion 55 and extends along the flat surface portion 51. That is, at least a part of each bus bar 42 extends along the first surface 51a of the flat surface portion 51. At least a part of each bus bar 42 extends in the horizontal direction in the accommodation portion 55. Hereinafter, a portion of each bus bar 42 extending in a plate shape formed in the horizontal direction may be referred to as a “horizontal plate portion 42p”. The horizontal plate portion 42p is an example of a “plate portion”. The bus bar 42 is a member that forms a horizontal energization path. The bus bar 42 may be referred to as a “horizontal routing member”. Each bus bar 42 includes, for example, a connection portion 61, a connection portion 62, and an extending portion 63.

The connection portion 61 is located in the middle of the bus bar 42 or at the first end of the bus bar 42. The connection portion 61 is a portion connected to the electronic component 10 (for example, the electronic component 10S) directly or via the connection component 20. The connection portion 61 includes, for example, a portion overlapping the connection component 20 when viewed from the Z direction. The connection portion 61 is adjacent to the connection component 20 in the Z direction and is connected to the connection component 20 from the Z direction. Instead of the above example, for example, the connection portion 61 may be adjacent to the terminal 13 of the electronic component 10 in the Z direction and directly connected to the terminal 13 of the electronic component 10 from the Z direction.

The connection portion 62 is located in the middle of the bus bar 42 or at the second end of the bus bar 42. The connection portion 62 is a portion connected to another electronic component 10 directly or via another connection component 20.

Instead of the above example, the connection portion 62 may be connected to another bus bar 42 (for example, the bus bar 42 included in another subunit SU) or an external connection bus bar 76 (see FIG. 2).

The extending portion 63 extends from the connection portion 61 in the X direction or the Y direction. The extending portion 63 is provided between the connection portion 61 and the connection portion 62. The extending portion 63 extends over the connection portion 61 and the connection portion 62. The extending portion 63 connects the connection portion 61 to the connection portion 62.

In the present embodiment, the horizontal plate portion 42p described above includes at least the entire connection portion 61 and a part of the extending portion 63. That is, at least the entire connection portion 61 and a part of the extending portion 63 are accommodated in the accommodation portion 55 and located on the same plane.

### <4.3.3 Fastening Member>

Next, the fastening member 43 will be described.

FIG. 7 is a cross-sectional view taken along line F7-F7 of the structure illustrated in FIG. 3. The fastening member 43 is a component for fixing the bus bar 42 to the connection component 20 corresponding to the bus bar 42. The fastening member 43 is, for example, a caulking bolt fixed to the bus bar 42. The fastening member 43 is an example of a “fastening portion”.

In the present embodiment, at least one of the connection portion 61 and the connection portion 62 of the bus bar 42 has an attachment hole 42h. The attachment hole 42h is, for example, a through-hole penetrating the bus bar 42 in the Z direction. The fastening member 43 is, for example, a bolt having a shaft 43a and a head 43b. A circumferential surface of the shaft 43a has a screw groove. The head 43b has a diameter larger than that of the shaft 43a. The head 43b of the fastening member 43 is caulked and fixed to the bus bar 42 in a state in which the shaft 43a passes through the attachment hole 42h of the bus bar 42. With this fixation, the fastening member 43 is electrically and physically connected to the bus bar 42 in a state in which the shaft 43a protrudes in the +Z direction from the attachment hole 42h of the bus bar 42. The fastening member 43 is not limited to caulking fixation, and may be fixed to the bus bar 42 through welding or other methods.

In the present embodiment, the connection component 20 is attached to the fastening member 43 from the Z direction in a state of being previously fixed to the electronic component 10 via the fastening member 71. For example, in the connection component 20, the shaft 43a of the fastening member 43 is inserted into the second attachment hole 22h of the second portion 22. The engagement member 44 (for example, a nut) is engaged with the shaft 43a of the fastening member 43 protruding from the second attachment hole 22h of the second portion 22 of the connection component 20. The engagement member 44 is attached to the shaft 43a in the Z direction. This engagement fixes the second portion 22 of the connection component 20 to the fastening member 43.

### (Heat Transfer Member)

First, the heat transfer member 120 will be described. The heat transfer member 120 is a member for transferring heat generated by the electronic component 10 (for example, the electronic component 10S) at the time of energization and/or heat (Joule heat) generated by the bus bar 42 itself at the time of energization to the metal plate 110. The heat transfer member 120 is, for example, a heat transfer sheet (for example, a thermally conductive silicone sheet) having elasticity. The heat transfer member 120 is made of a material having a higher thermal conductivity than the base plate 41S (or the base member 41T that will be described later), for example. However, the heat transfer member 120 is not limited to the above example, and may be a heat transfer member formed of a thermally conductive gel or another material. In the present embodiment, the heat transfer member 120 has an insulating property.

In the present embodiment, the heat transfer member 120 is partially provided in the routing board 40S (see FIG. 2). For example, the heat transfer member 120 is disposed at a position overlapping a part of the bus bar 42 when viewed from the Z direction. The heat transfer member 120 is disposed between the bus bar 42 and a flat surface portion 111 of the metal plate 110 that will be described later. For example, the heat transfer member 120 is disposed between the exposed portion 42u of the bus bar 42 and the flat surface portion 111 of the metal plate 110, and is in contact with the exposed portion 42u of the bus bar 42 and the flat surface portion 111 of the metal plate 110. The heat transfer member 120 transfers heat transferred from the electronic component 10 (for example, the electronic component 10S) to the bus bar 42 and/or heat generated by the bus bar 42 from the bus bar 42 to the flat surface portion 111 of the metal plate 110.

In the present embodiment, the heat transfer member 120 is disposed at a position overlapping a part of the bus bar 42 in the vicinity of the electronic component 10 (for example, the electronic component 10S) when viewed from the Z direction. In the present embodiment, the heat transfer member 120 is disposed at a position overlapping the connection component 20 when viewed from the Z direction. In other words, the heat transfer member 120 is disposed at a position overlapping the connection portion 61 or the connection portion 62 of the bus bar 42 when viewed from the Z direction. The heat transfer member 120 transfers heat transferred from the electronic component 10S to the bus bar 42 via the connection component 20 from the bus bar 42 to the flat surface portion 111 of the metal plate 110.

### <4.4 Fixing Structure of Routing Board and Electronic Component>

Next, a fixing structure of the routing board 40S and the electronic component 10 will be described.

FIG. 8 is a cross-sectional view taken along line F8-F8 of the structure illustrated in FIG. 3. The metal plate 110 includes, for example, a fixing portion 112 and a fixing portion 113 in addition to a flat surface portion 111 that will be described later.

The fixing portion 112 is a fixing portion for fixing the base plate 41S to the metal plate 110. The fixing portion 112 is provided at a position corresponding to the fixing portion 53 of the base plate 41S when viewed from the Z direction. The fixing portion 112 is a cylindrical or prismatic boss protruding in the +Z direction from the flat surface portion 111 of the metal plate 110. The fixing portion 112 has an engagement hole 112h that is open in the +Z direction. An inner circumferential surface of the engagement hole 112h has a screw groove.

As described above, the fixing portion 53 of the base plate 41S has an attachment hole 53h. A fastening member 115 (for example, a screw or a bolt) passes through the attachment hole 53h. When the fastening member 115 that has passed through the attachment hole 53h of the fixing portion 53 of the base plate 41S is engaged with the engagement hole 112h of the fixing portion 112 of the metal plate 110, the base plate 41S is fixed to the metal plate 110.

The fixing portion 113 is a fixing portion for directly fixing the electronic component 10 (for example, the electronic component 10S) to the metal plate 110 without the base plate 41S interposed therebetween. The fixing portion 113 is provided at a position corresponding to the attachment portion 14 of the electronic component 10 when viewed from the Z direction. The fixing portion 113 is a cylindrical or prismatic boss protruding in the +Z direction from the flat surface portion 111. The fixing portion 113 has an engagement hole 113h that is open in the +Z direction. An inner circumferential surface of the engagement hole 113h has a screw groove.

In the present embodiment, the flat surface portion 51 of the base plate 41S has a through-hole 51h. The through-hole 51h penetrates the flat surface portion 51 in the Z direction. The through-hole 51h is provided at a position corresponding to the fixing portion 113 of the metal plate 110 when viewed from the Z direction. The fixing portion 113 of the metal plate 110 passes through the through-hole 51h of the base plate 41S and protrudes to the same position as the first surface 51a of the flat surface portion 51 or further toward the +Z direction side than the first surface 51a of the flat surface portion 51. The attachment portion 14 of the electronic component 10 is in contact with the fixing portion 113 at the same position as the first surface 51a of the flat surface portion 51 or at a position located further toward the +Z direction side than the first surface 51a of the flat surface portion 51.

A fastening member 116 (for example, a screw or a bolt) passes through the attachment hole 14h of the attachment portion 14 of the electronic component 10 from the +Z direction side. When the fastening member 116 that has passed through the attachment hole 14h of the attachment portion 14 of the electronic component 10 is engaged with the engagement hole 113h of the fixing portion 113 of the metal plate 110, the electronic component 10 is fixed to the metal plate 110 without the base plate 41S interposed therebetween. Note that, instead of the above-described example, the electronic component 10 may be fixed to a fixing portion provided in the base plate 41S.

### 5. Constitution of Subunit SUT

Next, a constitution of the subunit SUT will be described.

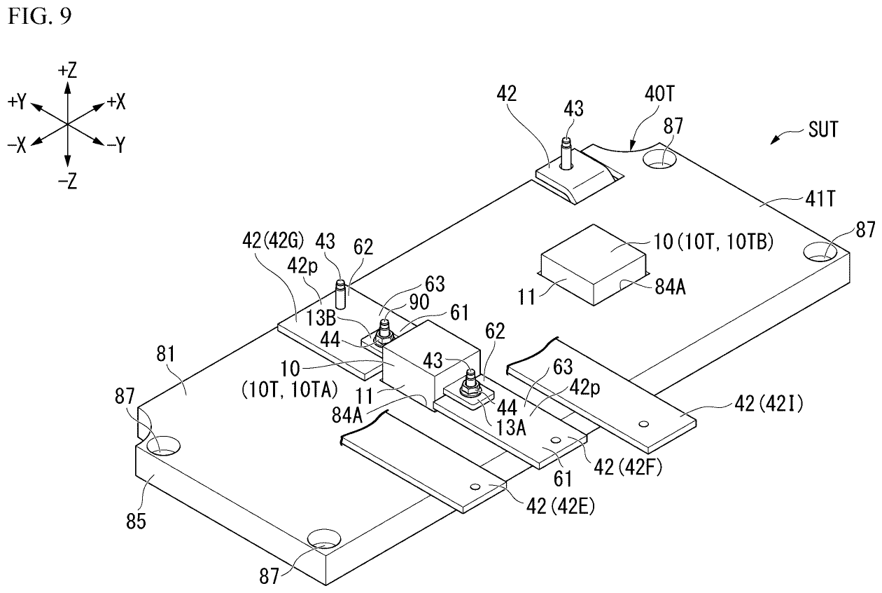

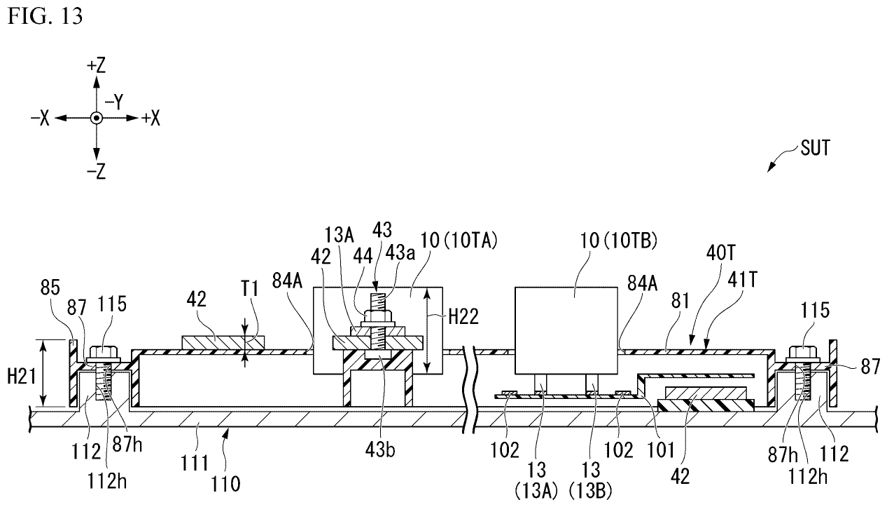

FIG. 9 is a perspective view illustrating the subunit SUT. The subunit SUT includes, for example, a plurality of electronic components 10, a routing structure 40T, and an auxiliary base member 101 (see FIG. 13).

### <5.1 Electronic Component>

First, the electronic component 10 will be described. The plurality of electronic components 10 include a plurality of electronic components 10TA (only one is illustrated in FIG. 9) and a plurality of electronic components 10TB (only one is illustrated in FIG. 9). Note that the plurality of electronic components 10 may include only one of the electronic component 10TA and the electronic component 10TB.

The electronic component 10TA is an example of the electronic component 10T described above. The electronic component 10TA is an electronic component having a smaller amount of heat generation than the electronic component 10S when energized. On the other hand, the electronic component 10TB is another example of the electronic component 10T described above. The electronic component 10TB is an electronic component having a lower mountability (for example, requiring a complicated implementation structure) than the electronic component 10S. The electronic component 10TB has, for example, a terminal 13 protruding in the −Z direction toward the flat surface portion 111 of the metal plate 110 (see FIG. 13). For example, the electronic component 10TB has a smaller amount of heat generation than the electronic component 10S when energized. As described above, the amount of heat generation of the electronic component 10T may be greater than the amount of heat generation of the electronic component 10S.

Hereinafter, in a case where the electronic component 10TA and the electronic component 10TB are not distinguished, the electronic components are simply referred to as “electronic component 10T”. The electronic component 10T is, for example, a connector, a fuse, a capacitor, a branch component, any of various sensors (for example, a current sensor or a voltage sensor), an electronic control unit, or an electronic component unit in which two or more of these are unitized. However, the type of the electronic component 10T is not limited to the above example.

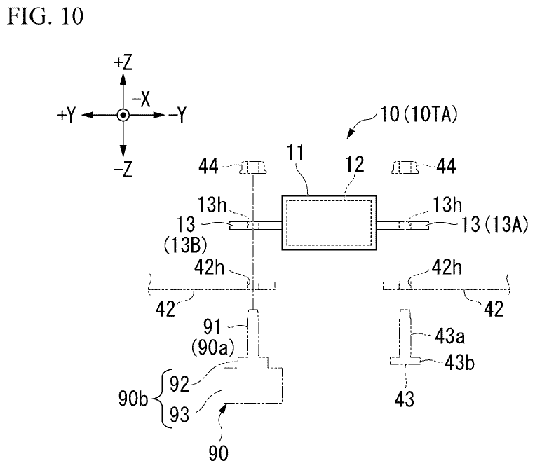

FIG. 10 is a front view illustrating the electronic component 10TA. The electronic component 10TA is, for example, an electronic component in which a plurality of terminals 13 are separately disposed at both ends of the electronic component 10TA in the horizontal direction. In the present embodiment, the terminal 13A and the terminal 13B are disposed separately at both ends of the electronic component 10TA in the Y direction. The terminals 13A and 13B protrude in the horizontal direction (for example, the +Y direction or the −Y direction) from the center of the case 11 in the Z direction. Each terminal 13 is, for example, a plate portion provided in the horizontal direction. Each terminal 13 has an attachment hole 13h through which a fastening member 43 (for example, a screw or a bolt) or a fastening member 90 that will be described later passes. The attachment hole 13h is open in the Z direction. An inner circumferential surface of the attachment hole 13h has no screw groove. The attachment hole 13h is a through-hole penetrating the terminal 13 in the Z direction.

### <5.2 Routing Structure>

Next, referring to FIG. 9 again, the routing structure 40T will be described. The routing structure 40T is a member that forms at least a part of an energization path between the plurality of electronic components 10 (for example, the plurality of electronic components 10T) and/or at least a part of an energization path between the electronic component 10 (for example, the electronic component 10T) included in the subunit SUT and the electronic component 10 included in another subunit SU (for example, the subunit SUS). The routing structure 40T includes, for example, a base member 41T, one or more (for example, a plurality of) bus bars 42, a plurality of fastening members 43, and a fastening member 90 having a heat storage function. Note that the content of the fastening member 43 is similar to that of the fastening member 43 described in the subunit SUS, and thus repeated description will be omitted.

### <5.2.1 Base Member>

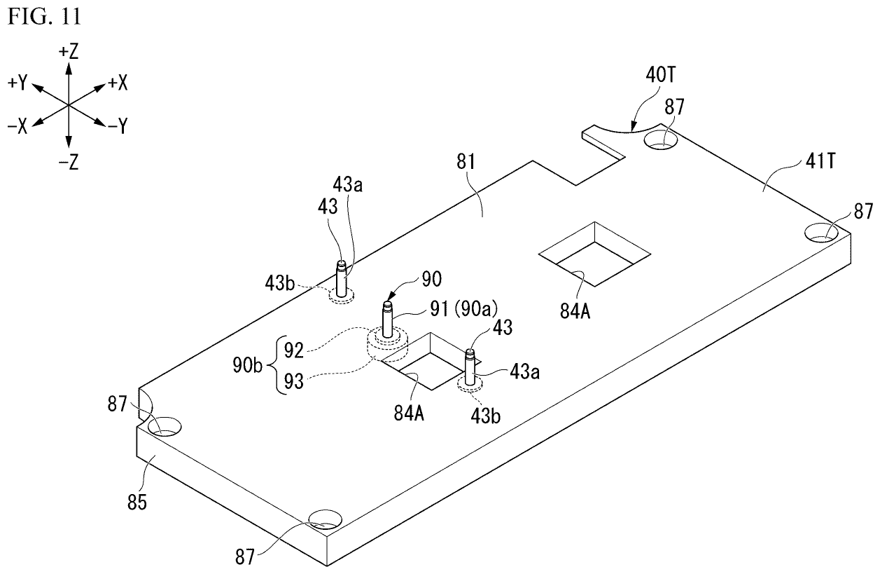

FIG. 11 is a perspective view illustrating the base member 41T. The base member 41T is a support member that integrally supports the plurality of bus bars 42 arranged at intervals in the horizontal direction. The base member 41T is made of, for example, a synthetic resin and has an insulating property. The base member 41T electrically insulates the plurality of bus bars 42 from each other by using, for example, a rib (not illustrated). The base member 41T may be referred to as an “insulating substrate”. The base member 41T has a three-dimensional structure thicker in the Z direction than the base plate 41S included in the subunit SUS. The base member 41T includes, for example, a support wall 81, a frame portion 85 (peripheral wall portion), and a fixing portion 87.

### (Support Wall)

The support wall 81 is, for example, a plate-shaped wall portion provided in the horizontal direction. The plurality of bus bars 42 are disposed on the support wall 81 and are supported from below by the support wall 81 (see FIG. 9). The support wall 81 that supports the bus bar 42 is not limited to a wall portion provided in the horizontal direction, and may be a grid-shaped wall portion formed by a plurality of ribs extending in the Z direction. In the present embodiment, the fastening member 43 and the fastening member 90 are attached to the support wall 81. The fastening member 43 and the fastening member 90 protrude from the support wall 81 in the +Z direction.

### (Accommodation Portion Accommodating Electronic Component)

In the present embodiment, the base member 41T has an accommodation portion 84A that is open to the +Z direction side. The accommodation portion 84A is, for example, a recess in which a part of the support wall 81 is recessed in the Z direction or a through-hole penetrating the support wall 81 in the Z direction. The accommodation portion 84A has an outer shape corresponding to the shape of the case 11 (that is, the component body 12) of the electronic component 10 (for example, the electronic component 10T) when viewed from the Z direction. At least a part of the electronic component 10 (for example, the electronic component 10T) (for example, at least a part of the component body 12) is accommodated in the accommodation portion 84A. At least a part of the electronic component 10 accommodated in the accommodation portion 84A is located on the −Z direction side compared with the support wall 81.

### (Frame Portion)

The frame portion 85 is provided at a peripheral end of the base member 41T. The frame portion 85 is a rib (peripheral wall portion) extending in the Z direction at the peripheral end of the base member 41T. A width (thickness) H21 of the frame portion 85 (peripheral wall portion) in the Z direction is, for example, half or more of a width (thickness) H22 of the electronic component 10 (for example, the electronic component 10TA) in the Z direction (see FIG. 13). Note that the frame portion 85 may be omitted.

### (Fixing Portion)

The fixing portion 87 is a portion fixed to the metal plate 110 (see FIG. 13). The fixing portion 87 faces the fixing portion 112 of the metal plate 110 in the Z direction. The fixing portion 87 has an attachment hole 87 h penetrating the base member 41T in the Z direction. A fastening member 115 (for example, a screw or a bolt) passes through the attachment hole 87h. When the fastening member 115 that has passed through the attachment hole 87h is engaged with the engagement hole 112h of the fixing portion 112 of the metal plate 110, the base member 41T is fixed to the metal plate 110.

### <5.2.2 Bus Bar>

Next, the bus bar 42 included in the routing structure 40T will be described.

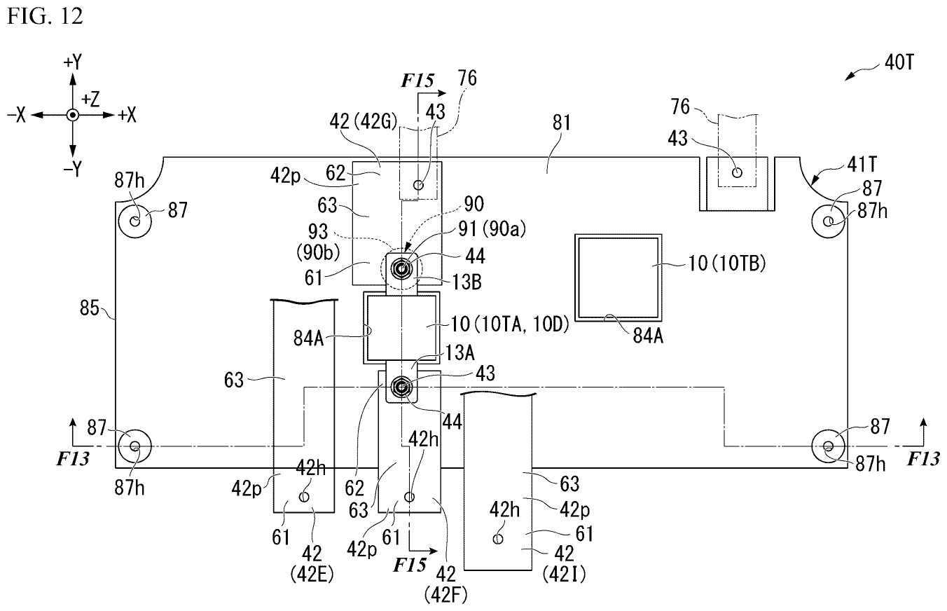

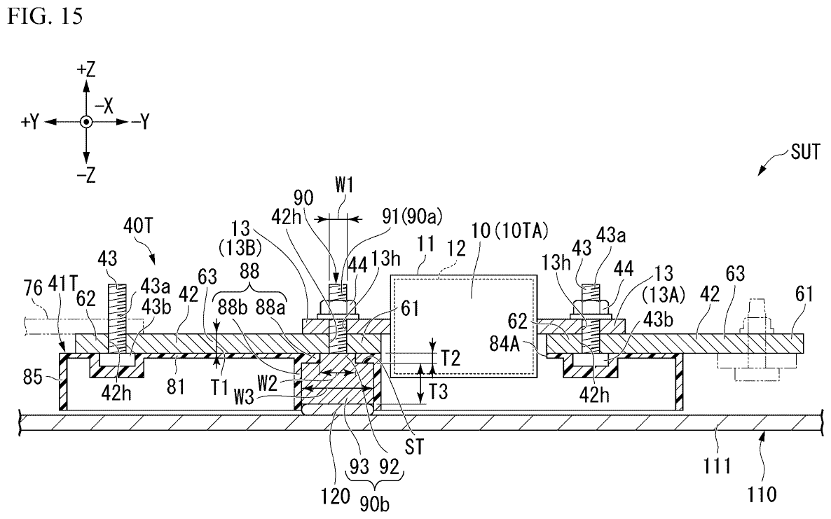

FIG. 12 is a plan view illustrating the subunit SUT. The bus bar 42 is a routing member (electrical connection member) included in the routing structure 40T. The bus bar 42 is, for example, a routing member for electrically connecting a plurality of electronic components 10 (for example, a plurality of electronic components 10T). Alternatively, the bus bar 42 may be a routing member for connecting the electronic component 10 (for example, the electronic component 10T) to the electronic component 10 included in another subunit SU (for example, the subunit SUS). In the present embodiment, the plurality of bus bars 42 are supported from below by the base member 41T and are disposed at positions away from the metal plate 110. The bus bar 42 is disposed immediately below the terminal 13 of the electronic component 10, for example. The bus bar 42 overlaps the component body 12 of the electronic component 10 when viewed from the X direction or the Y direction (see FIG. 15).

The plurality of bus bars 42 include, for example, four bus bars 42E, 42F, 42G, and 42I. The four bus bars 42E, 42F, 42G, and 42I are disposed to be arranged at intervals in the horizontal direction. The four bus bars 42E, 42F, 42G, and 42I include portions disposed on the same plane. At least a part of each bus bar 42 is the horizontal plate portion 42p. In the present embodiment, each bus bar 42 has a plate shape formed in the horizontal direction over the entire length. The horizontal plate portion 42p of each bus bar 42 includes the connection portion 61, the connection portion 62, and the extending portion 63. In the present embodiment, the subunit SUT includes an electronic component 10D as one of the electronic components 10TA.

The connection portion 61 of the bus bar 42E is connected to the bus bar 42 included in the subunit SUS. Similarly, the connection portion 61 of the bus bar 42F is connected to the bus bar 42 included in the subunit SUS. The connection portion 62 of the bus bar 42F is physically and electrically connected to the terminal 13A of the electronic component 10D. For example, the terminal 13A of the electronic component 10D is placed on the horizontal plate portion 42p of the bus bar 42F to be connected to the connection portion 62 of the bus bar 42F.

The connection portion 61 of the bus bar 42G is physically and electrically connected to the terminal 13B of the electronic component 10D. For example, the terminal 13B of the electronic component 10D is placed on the horizontal plate portion 42p of the bus bar 42G to be connected to the connection portion 61 of the bus bar 42G. The connection portion 61 of the bus bar 42G is an example of a “first connection portion”. The connection portion 62 of the bus bar 42G is physically and electrically connected to the external connection bus bar 76. The connection portion 62 of the bus bar 42G is connected to an external device via the bus bar 76. The connection portion 62 of the bus bar 42G is an example of a “second connection portion”. The bus bar 76 is an example of an “external connection component”. Note that the connection portion 62 of the bus bar 42G may be physically and electrically connected to the terminal 13 of another electronic component 10 instead of the bus bar 76.

The connection portion 61 of the bus bar 42I is connected to the bus bar 42 included in the subunit SUS. The connection portion 62 of the bus bar 42I is physically and electrically connected to the terminal 13A of the electronic component 10T (not illustrated).

### <5.3 Auxiliary Base Member>

Next, the auxiliary base member 101 will be described.

FIG. 13 is a cross-sectional view taken along line F13-F13 of the structure illustrated in FIG. 12. The auxiliary base member 101 is made of, for example, a synthetic resin and has an insulating property. A plurality of wirings 102 are provided on the surface of the auxiliary base member 101. The wiring 102 is, for example, a conductive layer (metal layer) provided on the surface of the auxiliary base member 101. The auxiliary base member 101 is disposed between the base member 41T and the flat surface portion 111 of the metal plate 110 in the Z direction. The auxiliary base member 101 faces the electronic component 10TB from the −Z direction side. The terminal 13 of the electronic component 10TB is electrically connected to the wiring 102 provided on the auxiliary base member 101 at a position between the base member 41T and the flat surface portion 111 of the metal plate 110. The auxiliary base member 101 is an example of a “third base member”.

### <5.4 Fastening Member Having Heat Storage Function>

### <5.4.1 Function of Fastening Member>

Next, the fastening member 90 having a heat storage function will be described.

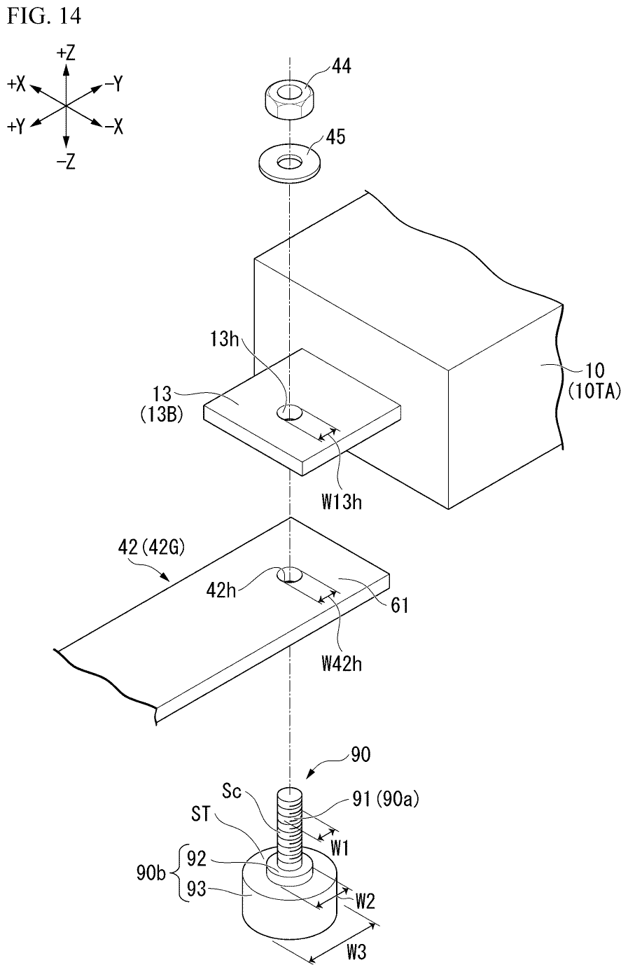

FIG. 14 is a perspective view showing the fastening member 90. The fastening member 90 has a larger heat storage capacity than a general fastening member (for example, the fastening member 43), and is a fastening member that physically and electrically connects a plurality of members. The fastening member 90 is made of metal and has a conductivity. A material of the fastening member 90 is, but is not limited to, copper, a copper alloy, aluminum, an aluminum alloy, steel, stainless steel, magnesium, a magnesium alloy, titanium, a titanium alloy, or the like. The fastening member 90 may be referred to as a “heat storage member” or a “metal member”.

The fastening member 90 fastens the first member to the second member. For example, the fastening member 90 fastens the electronic component 10 to the bus bar 42. The electronic component 10 is an example of a “first member”. The connection component 20 is an example of a “second member”. In the present disclosure, the term “fasten” or “fix” is not limited to the case of fastening or fixing using a single component (fastening member 90), and may include the case of fastening or fixing in combination with another component (for example, the engagement member 44 such as a nut).

The first member and the second member are not limited to the above example. For example, the first member is any one of the electronic component 10, a connection component (for example, the connection component 20) attached to the electronic component 10, the bus bar 42, or the external connection bus bar 76. For example, the second member is any one of the electronic component 10, a connection component (for example, the connection component 20) attached to the electronic component 10, the bus bar 42, or the external connection bus bar 76. For example, the fastening member 90 may fix the bus bar 42 to another bus bar 42 (or the external connection bus bar 76), or fasten the connection component 20 attached to the electronic component 10 to the bus bar 42.

Hereinafter, as an example of the fastening member 90, the fastening member 90 that fastens the electronic component 10 (first member) to the bus bar 42 (second member) will be described. However, in the following description, the terms “electronic component 10″ and ”bus bar 42″ may be appropriately replaced with different members on the basis of the gist described above.

As illustrated in FIG. 14, the terminal 13 of the electronic component 10 has an attachment hole 13h. The attachment hole 13h is, for example, a through-hole penetrating the terminal 13 in the Z direction. An inner circumferential surface of the attachment hole 13h has no screw groove. However, as described above, the “attachment hole” in the present disclosure is not limited to a hole having no screw groove, and may be a hole having screw groove. In the present disclosure, the “attachment hole” is not limited to a through-hole, and may be a bottomed hole. For example, the attachment hole 13h may be a hole having a screw groove and engaged with the shaft 91 of the fastening member 90. The attachment hole 13h may be a bottomed hole. The attachment hole 13h is an example of a “first attachment hole”.

Similarly, the connection portion 61 of the bus bar 42 has an attachment hole 42h. The attachment hole 42h is, for example, a through-hole penetrating the bus bar 42 in the Z direction. An inner circumferential surface of the attachment hole 42h has no screw groove. However, the attachment hole 42h may be a hole having a screw groove and engaged with the shaft 91 of the fastening member 90. The attachment hole 42h may be a bottomed hole. The attachment hole 42h is an example of a “second attachment hole”. In a case where one of the attachment hole 13h of the electronic component 10 and the attachment hole 42h of the bus bar 42 is a hole having a screw groove, the engagement member 44 can be omitted.

### <5.4.2 Structure of Fastening Member>

Next, a structure of the fastening member 90 will be described. The fastening member 90 includes, for example, a shaft 91, a base portion 92, and a heat storage portion 93.

### (Shaft)

The shaft 91 is a cylindrical portion having a screw thread Sc on the outer circumferential surface. The shaft 91 extends in the Z direction. The shaft 91 is inserted into the attachment hole 13h of the electronic component 10 and the attachment hole 42h of the bus bar 42 in a state in which the attachment hole 13h of the electronic component 10 and the attachment hole 42h of the bus bar 42 overlap each other in the Z direction. In the present embodiment, the tip of the shaft 91 that has passed through the attachment hole 13h of the electronic component 10 and the attachment hole 42h of the bus bar 42 passes through a washer 45, and is engaged with the engagement member 44 (for example, a nut).

### (Base Portion)

The base portion 92 is a portion thicker in the horizontal direction than the shaft 91. The base portion 92 has, for example, a flat cylindrical shape. A width W2 (for example, a diameter) of the base portion 92 in the Y direction (or the X direction) is larger than a width W1 (for example, a diameter) of the shaft 91 in the Y direction (or the X direction). A width W2 (for example, a diameter) of the base portion 92 in the Y direction (or the X direction) is larger than a width W13h (for example, a diameter) of the attachment hole 13h of the electronic component 10 in the Y direction (or the X direction). The width W2 (for example, a diameter) of the base portion 92 in the Y direction (or the X direction) is larger than a width W42h (for example, a diameter) of the attachment hole 42h of the bus bar 42 in the Y direction (or the X direction). The base portion 92 is disposed on the −Z direction side with respect to the terminal 13 of the electronic component 10 and the bus bar 42. The base portion 92 faces the terminal 13 of the electronic component 10 or the bus bar 42 in the Z direction.

### (Heat Storage Portion)

The heat storage portion 93 is a portion provided to secure a large heat capacity. The heat storage portion 93 is provided on the side opposite to the shaft 91 with respect to the base portion 92. The heat storage portion 93 is formed integrally with the base portion 92. In the present embodiment, the heat storage portion 93 is a solid cylindrical portion extending in the Z direction. In the present embodiment, the volume (heat capacity) of the heat storage portion 93 is twice or more the volume (heat capacity) of the engagement member 44 (for example, a nut).

In the present embodiment, the heat storage portion 93 bulges in the horizontal direction with respect to the base portion 92. A width W3 of the heat storage portion 93 in the Y direction (or X direction) is larger than the width W2 of the base portion 92 in the Y direction (or X direction). With this structure, a step ST in the horizontal direction is formed between the base portion 92 and the heat storage portion 93. However, the width W3 of the heat storage portion 93 in the Y direction (or the X direction) may be the same as the width W2 of the base portion 92 in the Y direction (or the X direction). That is, the step ST need not exist between the base portion 92 and the heat storage portion 93. In the present embodiment, the width W3 of the heat storage portion 93 in the Y direction (or the X direction) is twice or more the width W1 of the shaft 91 in the Y direction (or the X direction).

In the present embodiment, a thickness T3 of the heat storage portion 93 in the Z direction is larger than a thickness T2 of the base portion 92 in the Z direction. For example, the thickness T3 of the heat storage portion 93 in the Z direction is twice or more the thickness T2 of the base portion 92 in the Z direction. The end of the heat storage portion 93 on the −Z direction side is located near the flat surface portion 111 of the metal plate 110 beyond, for example, a midpoint in the Z direction between the bus bar 42 fastened by the fastening member 90 and the flat surface portion 111 of the metal plate 110.

In the present embodiment, the sum of the thickness T2 of the base portion 92 in the Z direction and the thickness T3 of the heat storage portion 93 in the Z direction is larger than the thickness T1 of the horizontal plate portion 42p of the bus bar 42 in the Z direction (see FIG. 15). For example, the thickness T3 of the heat storage portion 93 in the Z direction is larger than the thickness T1 of the horizontal plate portion 42p of the bus bar 42 in the Z direction. For example, the thickness T3 of the heat storage portion 93 in the Z direction is twice or more the thickness T1 of the horizontal plate portion 42p of the bus bar 42 in the Z direction.

From another viewpoint, the fastening member 90 includes a first portion 90a and a second portion 90b.

The first portion 90a is a portion formed by the above-described shaft 91. The first portion 90a is a cylindrical portion extending in the Z direction. The outer circumferential surface of the first portion 90a has a screw thread Sc. The first portion 90a passes through the washer 45 and is engaged with the engagement member 44 (for example, a nut).

The second portion 90b is a portion formed by the base portion 92 and the heat storage portion 93 described above. The second portion 90b is a cylindrical portion having the step ST and including an enlarged diameter portion. In the present embodiment, the volume (heat capacity) of the second portion 90b is twice or more the volume (heat capacity) of the engagement member 44 (for example, the nut).

Note that, instead of being provided to correspond to one terminal 13 of the electronic component 10, the fastening member 90 may be provided to correspond to each of the two terminals 13A of the electronic component 10. The same applies to modification examples and other embodiments described below.

### <5.4.3 Structure Related to Fastening Member>

FIG. 15 is a cross-sectional view taken along line F15-F15 of the structure illustrated in FIG. 12. In the present embodiment, the base member 41T includes a holding portion 88 that holds the heat storage portion 93. The holding portion 88 includes, for example, a first portion 88a and a second portion 88b.

The first portion 88a is located between the bus bar 42 (or the terminal 13 of the electronic component 10) and the heat storage portion 93 in the Z direction. The first portion 88a is adjacent to the base portion 92 in the X direction or the Y direction. The first portion 88a faces the step ST between the base portion 92 and the heat storage portion 93 in the Z direction. The first portion 88a faces the heat storage portion 93 in the Z direction and supports the heat storage portion 93 in the Z direction.

The second portion 88b is, for example, a tubular portion extending in the −Z direction from a peripheral edge of the first portion 88a. The second portion 88b faces the heat storage portion 93 in the X direction or the Y direction. The second portion 88b surrounds the heat storage portion 93 along the outer circumference of the heat storage portion 93. The second portion 88b supports the heat storage portion 93 in the horizontal direction.

In the present embodiment, the fastening member 90 is formed integrally with the base member 41T through insert molding. For example, the fastening member 90 is formed integrally with the holding portion 88 through insert molding, and is supported by the holding portion 88.

In the present embodiment, the heat storage portion 93 is located between the shaft 91 and the flat surface portion 111 of the metal plate 110. That is, the metal plate 110 faces the heat storage portion 93 from the side opposite to the terminal 13 or the bus bar 42 of the electronic component 10. The heat transfer member 120 is disposed between the heat storage portion 93 and the flat surface portion 111 of the metal plate 110. The heat transfer member 120 is in contact with, for example, the heat storage portion 93 and the flat surface portion 111 of the metal plate 110. The heat transfer member 120 is sandwiched between the heat storage portion 93 and the flat surface portion 111 of the metal plate 110 and elastically deformed. The heat transfer member 120 thermally connects the heat storage portion 93 to the flat surface portion 111 of the metal plate 110.

The fastening member 90 is, for example, a heat absorbing member that increases the heat capacity of the energization path included in the subunit SUT. For example, the fastening member 90 stores (absorbs) part of heat transferred from an external device to the electronic component 10 (for example, the electronic component 10T) via the external connection bus bar 76. Alternatively, the fastening member 90 may store (absorb) at least part of the heat generated by the electronic component 10 and/or at least part of the heat generated by the bus bar 42 itself. In a case where the fastening member 90 is used as a heat storage member (heat absorbing member), the fastening member 90 need not be thermally connected to the metal plate 110.

In the present embodiment, the fastening member 90 also functions as, for example, a heat transfer portion that transfers part of heat directed from an external device to the electronic component 10 (for example, the electronic component 10T) via the external connection bus bar 76 to the flat surface portion 111 of the metal plate 110 that will be described later. In the present embodiment, the fastening member 90 is provided to correspond to the terminal 13B of the electronic component 10. According to this structure, part of heat directed from the external connection bus bar 76 to the electronic component 10 through the bus bar 42 easily moves to the fastening member 90 before reaching the electronic component 10.

Alternatively, the fastening member 90 may be a heat transfer portion that transfers at least part of heat generated by the electronic component 10 and/or at least part of heat generated by the bus bar 42 itself to the flat surface portion 111 of the metal plate 110. The flat surface portion 111 of the metal plate 110 is disposed away from the bus bar 42 in the Z direction. The flat surface portion 111 of the metal plate 110 faces the bus bar 42 in the Z direction. The flat surface portion 111 of the metal plate 110 is an example of a “facing portion”.

### <5.4.4 Modification Examples of Fastening Member>

Next, a modification example of the fastening member 90 will be described. Note that constitutions other than those described below in the present modification example are the same as those of the first embodiment.

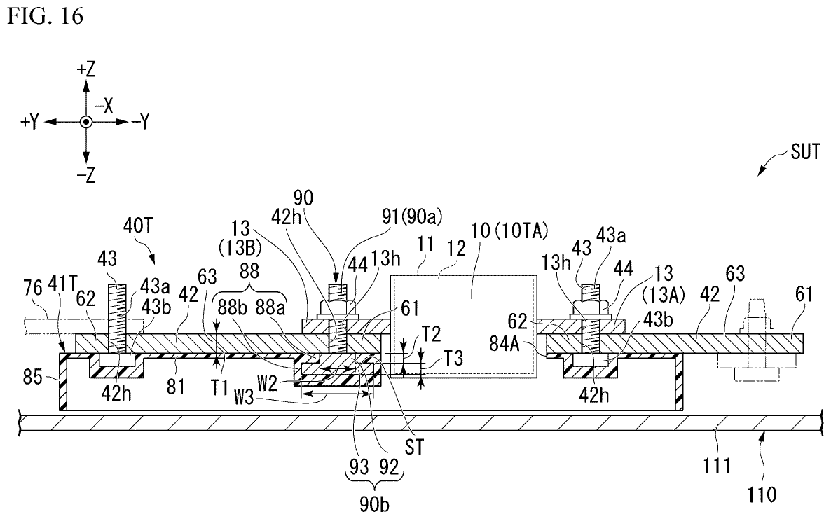

FIG. 16 is a cross-sectional view illustrating a subunit SUT of a modification example. As in the first embodiment, the fastening member 90 includes a shaft 91, a base portion 92, and a heat storage portion 93. In the example illustrated in FIG. 16, the thickness T3 of the heat storage portion 93 in the Z direction is substantially equal to the thickness T2 of the base portion 92 in the Z direction. However, also in the present modification example, the thickness T3 of the heat storage portion 93 in the Z direction may be larger than the thickness T2 of the base portion 92 in the Z direction as in the first embodiment.

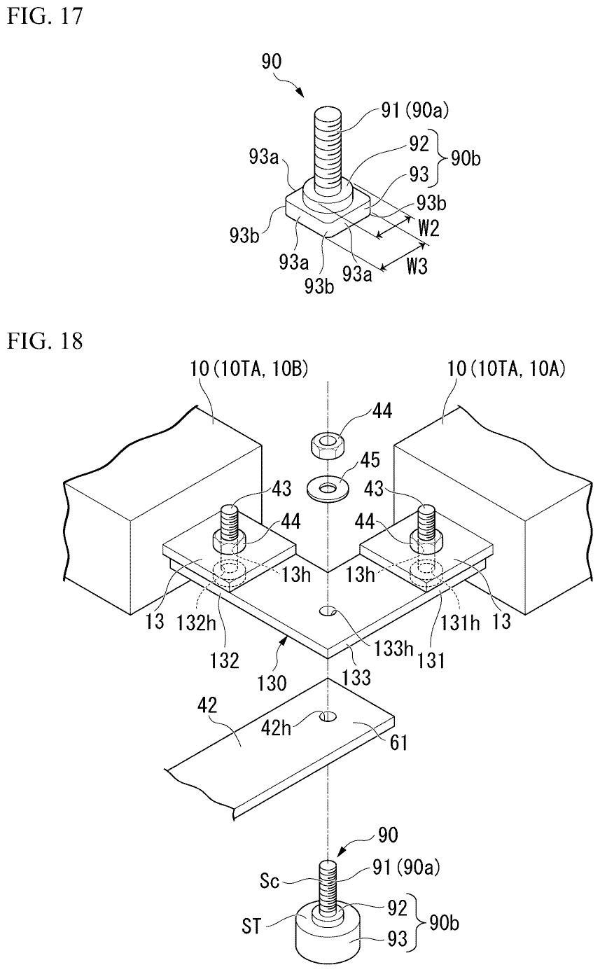

FIG. 17 is a perspective view illustrating a fastening member 90 according to a modification example. Also in the present modification example, the heat storage portion 93 bulges in the horizontal direction with respect to the base portion 92. A width W3 of the heat storage portion 93 in the Y direction (or X direction) is larger than the width W2 of the base portion 92 in the Y direction (or X direction).

In the present modification example, the base portion 92 has a perfect circle shape when viewed from the Z direction. On the other hand, the heat storage portion 93 is larger than the base portion 92 and has a shape different from a perfect circle or a regular polygon when viewed from the Z direction. For example, the heat storage portion 93 includes four straight portions 93a and four corner portions 93b provided between the four straight portions 93a when viewed from the Z direction. The corner portion 93b has an arc shape protruding outward in the horizontal direction. When viewed from the Z direction, the heat storage portion 93 has a shape having a larger area (volume) than a perfect circle having the same maximum width in the X direction and the Y direction as the heat storage portion 93. With this structure, the heat capacity of the fastening member 90 is further increased. The heat storage portion 93 may have a shape such as a regular polygon (for example, a regular square) when viewed from the Z direction.

### 6. Metal Plate and Insulating Cover

Next, referring to FIG. 2 again, the metal plate 110 and the insulating cover 119 will be described.

### <6.1 Metal Plate>

The metal plate 110 is a member that secures rigidity of the electrical connection unit 1 and enhances the heat dissipation property of the electrical connection unit 1. The metal plate 110 is made of metal (for example, aluminum or an aluminum alloy). The metal plate 110 is an example of a “heat dissipation member”. The metal plate 110 may be referred to as a “metal member” or a “rigid member”.

The metal plate 110 has a rectangular shape formed in the X direction and the Y direction. The metal plate 110 has a first end 110e1, a second end 110e2, a third end 110e3, and a fourth end 110e4. The first end 110e1 and the second end 110e2 are a pair of ends of the metal plate 110 in the longitudinal direction, and are separated in the X direction. The third end 110e3 and the fourth end 110e4 are a pair of ends of the metal plate 110 in the lateral direction, and are separated in the Y direction. The metal plate 110 includes, for example, the flat surface portion 111, the plurality of fixing portions 112 (see FIG. 8) described above, and the plurality of fixing portions 113 (see FIG. 8) described above.

The flat surface portion 111 is a portion formed in a plate shape in the metal plate 110. The flat surface portion 111 has a plate shape formed in the horizontal direction. The flat surface portion 111 forms a main portion of the metal plate 110. The flat surface portion 111 forms a base portion (metal base portion) of the metal plate 110. The flat surface portion 111 has a size that covers the two subunits SU from below.

In the present embodiment, the flat surface portion 111 has a first region A1 and a second region A2. The first region A1 is, for example, a region on the −Y direction side in the flat surface portion 111. The subunit SUS described above faces the first region A1 of the flat surface portion 111 when viewed from the Z direction. That is, the plurality of electronic components 10S and the base plate 41S included in the subunit SUS face the first region A1 of the flat surface portion 111 in the Z direction.

The second region A2 is, for example, a region on the +Y direction side in the flat surface portion 111. The above-described subunit SUT faces the second region A2 of the flat surface portion 111 when viewed from the Z direction. That is, the plurality of electronic components 10T and the base member 41T included in the subunit SUT face the second region A2 of the flat surface portion 111 in the Z direction.

### <6.2 Insulating Cover>

The insulating cover 119 is a member for preventing the subunit SU from contacting the energization path. The insulating cover 119 is made of, for example, a synthetic resin and has an insulating property. The insulating cover 119 has, for example, a box shape that is open on the −Z direction side. The insulating cover 119 has a plurality of vent holes 119h. The insulating cover 119 covers a part or the whole of the corresponding subunit SU. Note that the insulating cover 119 is not limited to a box-shaped member, and may be a sheet-shaped member that covers the energization path of the main body MU. Further, the insulating cover 119 may be omitted.

### 7. Advantages

As a comparative example, a structure without the fastening member 90 will be considered. In such a structure, in a case where a sufficient heat capacity is not ensured in the electrical connection unit, a large temperature rise may occur in a part of the electrical connection unit and/or thermal interference with the electronic component may increase. For example, when a transient large current flows, a large temperature rise may occur in a part of the electrical connection unit and/or thermal interference with the electronic component may increase. Therefore, it may be difficult to improve the thermal characteristics of the electrical connection unit.

In the present embodiment, the electrical connection unit 1 has the fastening member 90. The fastening member 90 includes the shaft 91, the base portion 92, and the heat storage portion 93. The shaft 91 is inserted into the first attachment hole and the second attachment hole in a state in which the first attachment hole (for example, the attachment hole 13h) of the first member (for example, the electronic component 10) and the second attachment hole (for example, the attachment hole 42h) of the second member (for example, the bus bar 42) overlap each other in the first direction (Z direction). The shaft 91 has the screw thread Sc. The width of the base portion 92 in the X direction or the Y direction is larger than that of the shaft 91. The base portion 92 faces the first member or the second member in the Z direction. The heat storage portion 93 is provided on the side opposite to the shaft 91 with respect to the base portion 92. The heat storage portion 93 is formed integrally with the base portion 92.

According to such a constitution, the heat storage function (heat absorbing function) can be improved by using the member used as the fastening member 90. According to this constitution, part of heat transferred through the bus bar 42 can be stored (absorbed) at least temporarily by the fastening member 90. According to this structure, it is possible to suppress the occurrence of a large temperature rise in a part of the electrical connection unit 1 and/or the increase in thermal interference with the electronic component 10. As a result, it is possible to improve the thermal characteristics (for example, the heat dissipation property or the heat storage property) of the electrical connection unit 1 while suppressing the increase in the number of components of the electrical connection unit 1.

In the present embodiment, the width W3 of the heat storage portion 93 in the Y direction is larger than the width W2 of the base portion 92 in the Y direction. According to such a constitution, it is easy to secure a large heat capacity in the heat storage portion 93. In this structure, the thermal characteristics of the electrical connection unit 1 can be further improved.

In the present embodiment, a thickness T3 of the heat storage portion 93 in the Z direction is larger than a thickness T2 of the base portion 92 in the Z direction. According to such a constitution, it is easy to secure a large heat capacity in the heat storage portion 93. Therefore, the thermal characteristics of the electrical connection unit 1 can be further improved.

In the present embodiment, the heat storage portion 93 has an outer shape different from a regular circle and a regular polygon when viewed from the Z direction. According to such a constitution, it is easy to secure a large heat capacity in the heat storage portion 93 within a limited disposition area. Therefore, the thermal characteristics of the electrical connection unit 1 can be further improved.

In the present embodiment, the base member 41T includes a holding portion 88 that holds the heat storage portion 93. The holding portion 88 includes the first portion 88a and the second portion 88b. The first portion 88a is located between the first member and the heat storage portion 93 in the Z direction. The second portion 88b faces the heat storage portion 93 in the Y direction. According to such a constitution, the holding portion 88 that holds the heat storage portion 93 is obtained by using the difference in thickness between the base portion 92 and the heat storage portion 93. According to this structure, it is easy to improve the durability (for example, impact resistance) and the like of the electrical connection unit 1.

In the present embodiment, the electrical connection unit 1 includes the metal plate 110 and the heat transfer member 120. The metal plate 110 faces the heat storage portion 93 from a side opposite to the first member and the second member. The heat transfer member 120 is disposed between the heat storage portion 93 and the metal plate 110. According to such a structure, heat transferred from the first member or the second member to the fastening member 90 is easily released to the outside through the metal plate 110. According to this structure, it is possible to further improve the thermal characteristics of the electrical connection unit 1.

In the present embodiment, the fastening member 90 has the first portion 90a and the second portion 90b. The first portion 90a is inserted into the first attachment hole and the second attachment hole in a state in which the first attachment hole (for example, the attachment hole 13h) of the first member (for example, the electronic component 10) and the second attachment hole (for example, the attachment hole 42h) of the second member (for example, the bus bar 42) overlap each other in the first direction (Z direction). The first portion 90a has the screw thread Sc and is engaged with a nut (for example, the engagement member 44). The width of the second portion 90b in the X direction or the Y direction is larger than that of the first portion 90a. The second portion 90b faces the first member or the second member in the Z direction. The second portion 90b has a volume twice or more the volume of the nut. According to such a constitution, it is easy to secure a large heat capacity in the fastening member 90. With this structure, the thermal characteristics of the electrical connection unit 1 can be further improved.

### Second Embodiment

Next, a second embodiment will be described. The second embodiment is different from the first embodiment in that a fastening member 90 is attached to a connection component 130. Constitutions other than that described below are the same as the constitutions of the first embodiment.

FIG. 18 is a partially exploded perspective view illustrating a subunit SUT of the second embodiment. In the present embodiment, the electrical connection unit 1 includes a first electronic component 10A and a second electronic component 10B as a plurality of electronic components 10. The first electronic component 10A and the second electronic component 10B may be the same type of electronic component 10, or may be different types of electronic components 10.

In the present embodiment, the electrical connection unit 1 has a connection component 130. The connection component 130 is a member that is disposed between the electronic component 10 and the bus bar 42 and connects the electronic component 10 to the bus bar 42. In the present embodiment, the connection component 130 is a connection component that connects a plurality of electronic components (for example, electronic components 10A and 10B) to one bus bar 42. In the present embodiment, the connection component 130 is an example of a “first member”. The bus bar 42 is an example of a “second member”. The connection component 130 is made of metal (for example, made of copper, made of a copper alloy, made of aluminum, or made of an aluminum alloy). The connection component 130 includes, for example, a first portion 131, a second portion 132, and a third portion 133.

The first portion 131 is a portion physically and electrically connected to the terminal 13 of the first electronic component 10A. The first portion 131 is, for example, a plate portion provided in the horizontal direction. The first portion 131 faces the terminal 13 of the first electronic component 10A in the Z direction. The first portion 131 has an attachment hole 131h facing the attachment hole 13h of the terminal 13 of the first electronic component 10A. The first portion 131 is fixed to the terminal 13 of the first electronic component 10A by, for example, a fastening member 43 passing through the attachment hole 13h and the attachment hole 131h, and an engagement member 44 engaged with the fastening member 43.

The second portion 132 is a portion physically and electrically connected to the terminal 13 of the second electronic component 10B. The second portion 132 is, for example, a plate portion provided in the horizontal direction. The second portion 132 faces the terminal 13 of the second electronic component 10B in the Z direction. The second portion 132 has an attachment hole 132h facing the attachment hole 13h of the terminal 13 of the second electronic component 10B. The second portion 132 is fixed to the terminal 13 of the second electronic component 10B by, for example, the fastening member 43 passing through the attachment hole 13h and the attachment hole 132h and the engagement member 44 engaged with the fastening member 43.

The third portion 133 is a portion that couples the first portion 131 and the second portion 132 and is physically and electrically connected to the fastening member 90. The third portion 133 is, for example, a plate portion provided in the horizontal direction. The third portion 133 is provided between the first portion 131 and the second portion 132. The third portion 133 has an attachment hole 133h facing the attachment hole 42h of the bus bar 42. An inner circumferential surface of the attachment hole 133h does not have, for example, a screw groove. The attachment hole 133h is a through-hole penetrating the connection component 130 in the Z direction. However, the attachment hole 133h may be a hole having a screw groove and engaged with the shaft 91 of the fastening member 90. The attachment hole 133h may be a bottomed hole. In the present embodiment, the attachment hole 133h is an example of a “first attachment hole”. The attachment hole 42h of bus bar 42 is an example of a “second attachment hole”.

In the present embodiment, the shaft 91 of the fastening member 90 is inserted into the attachment hole 133h of the connection component 130 and the attachment hole 42h of the bus bar 42 in a state in which the attachment hole 133h of the connection component 130 and the attachment hole 42h of the bus bar 42 overlap each other in the Z direction. The fastening member 90 is thermally connected to the plurality of electronic components 10A and 10B via the connection component 130.

In the present embodiment, the fastening member 90 is thermally connected to the flat surface portion 111 of the metal plate 110 via the heat transfer member 120 as in the first embodiment. For example, the fastening member 90 also functions as a heat transfer portion that collectively transfers part of heat generated by the plurality of electronic components 10 to the flat surface portion 111 of the metal plate 110.

According to such a constitution, the temperature rise of the plurality of electronic components 10A and 10B can be suppressed by one fastening member 90. Through this operation, the electrical characteristics of the electrical connection unit 1 can be improved.

### Third Embodiment

Next, a third embodiment will be described. The third embodiment is different from the first embodiment in that an additional heat storage member 140 is provided.

The constitution other than that described below is the same as that of the first embodiment.

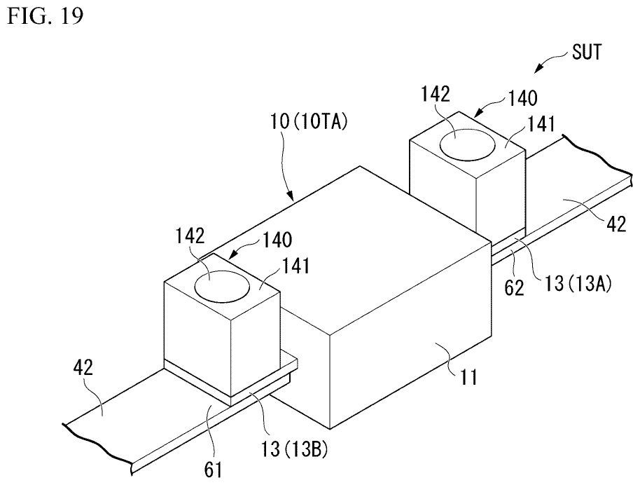

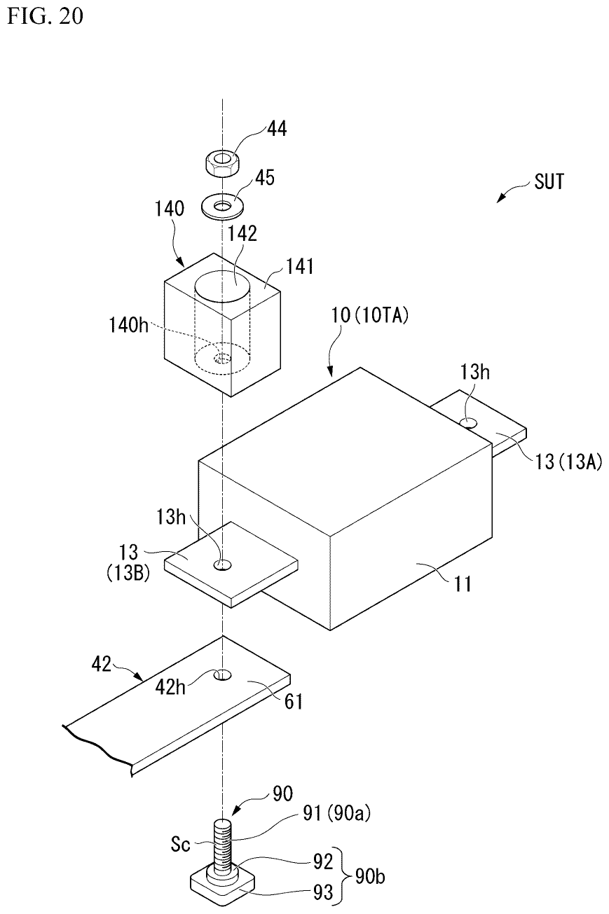

FIG. 19 is a perspective view illustrating a part of a subunit SUT of the third embodiment. FIG. 20 is a partially exploded perspective view illustrating the subunit SUT of the third embodiment. In the present embodiment, the subunit SUT has an additional heat storage member 140 in addition to the constitution of the first embodiment. The heat storage member 140 is disposed on a side opposite to the fastening member 90 with respect to the terminal 13 of the electronic component 10. The heat storage member 140 is made of metal (for example, made of copper, made of a copper alloy, made of aluminum, or made of an aluminum alloy). The heat storage member 140 may be referred to as a “metal member”. The heat storage member 140 includes a block 141 and a hole 142.

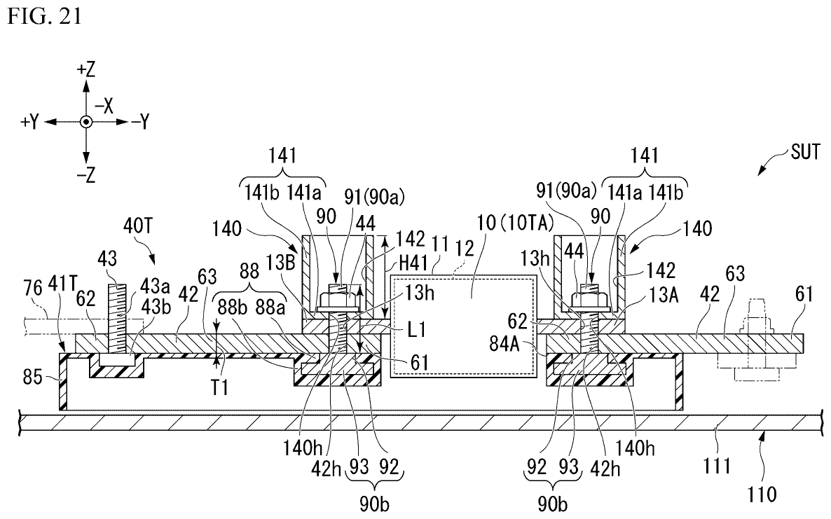

FIG. 21 is a cross-sectional view illustrating the subunit SUT of the third embodiment. The block 141 is a metal portion having a rectangular parallelepiped outer shape. A height H41 of the block 141 in the Z direction is larger than, for example, a half of a length L1 of the shaft 91 of the fastening member 90 in the Z direction. The height H41 of the block 141 in the Z direction is larger than the length L1 of the shaft 91 of the fastening member 90 in the Z direction, for example.

The hole 142 is provided in the block 141. The hole 142 is a cylindrical hole extending in the Z direction. The hole 142 is open in the +Z direction. The diameter of the hole 142 is larger than that of each of the engagement member 44 and the washer 45. By providing the hole 142, the block 141 has a bottom portion 141a and a peripheral wall portion 141b.

The bottom portion 141a is a plate portion provided in the horizontal direction. The bottom portion 141a faces the terminal 13 of the electronic component 10 in the Z direction. For example, the bottom portion 141a is placed on the terminal 13 of the electronic component 10 from the +Z direction side. The bottom portion 141a has an attachment hole 140h facing the attachment hole 13h of the terminal 13 of the electronic component 10.

An inner circumferential surface of the attachment hole 140h does not have, for example, a screw groove. The attachment hole 140h is a through-hole penetrating the bottom portion 141a in the Z direction. However, the attachment hole 140h may be a hole having a screw groove and engaged with the shaft 91 of the fastening member 90. The attachment hole 140h may be a bottomed hole that is open in the −Z direction. The peripheral wall portion 141b stands in the +Z direction from the bottom portion 141a. The peripheral wall portion 141b surrounds the periphery of the hole 142. The peripheral wall portion 141b extends, for example, toward the +Z direction side beyond the end on the +Z direction side of the shaft 91 of the fastening member 90.

In the present embodiment, the shaft 91 of the fastening member 90 is inserted into the attachment holes 42h, 13h, and 140h in a state in which the attachment hole 42h of the bus bar 42, the attachment hole 13h of the electronic component 10, and the attachment hole 140h of the heat storage member 140 overlap each other in the Z direction. The washer 45 passes through the tip of the shaft 91 that has passed through the attachment holes 42h, 13h, and 140h, and is engaged with the engagement member 44. With this constitution, the bus bar 42, the terminal 13 of the electronic component 10, and the heat storage member 140 are integrally fixed.

According to such a constitution, it is possible to further improve the thermal characteristics of the electrical connection unit 1 by providing the additional heat storage member 140.

### Fourth Embodiment

Next, a fourth embodiment will be described. The fourth embodiment is different from the first embodiment in that a fastening member 90 that fastens an electronic component 10 to a connection component 20 is provided. The constitution other than that described below is the same as that of the first embodiment.

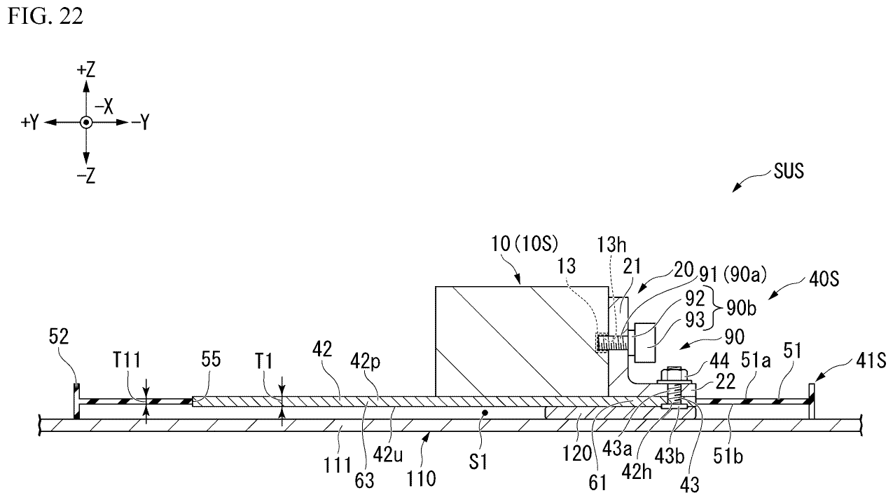

FIG. 22 is a cross-sectional view illustrating a subunit SUS of the fourth embodiment. In the present embodiment, the electrical connection unit 1 includes a fastening member 90 instead of the fastening member 71 described above. The shaft 91 of the fastening member 90 is inserted into the attachment hole 13h of the electronic component 10S and the attachment hole 21h of the connection component 20 in a state in which the attachment hole 13h of the electronic component 10S and the attachment hole 21h of the connection component 20 overlap each other. In the present embodiment, the shaft 91 of the fastening member 90 is engaged with the attachment hole 13h of the electronic component 10S. As a result, the electronic component 10S and the connection component 20 are fixed.

According to such a constitution, by providing the fastening member 90 fastening the electronic component 10S to the connection component 20, it is possible to further improve the thermal characteristics of the electrical connection unit 1 while suppressing an increase in the number of components of the electrical connection unit 1.

Several embodiments and modification examples have been described above. However, the embodiment and the modification examples are not limited to the examples described above. For example, the plurality of embodiments and modification examples described above may be implemented in combination with each other.

### DESCRIPTION OF REFERENCE SYMBOLS

1 Electrical connection unit
SU, SUS, SUT Subunit
10, 10S, 10T, 10TA, 10TB Electronic component
13, 13A, 13B Terminal
13h Attachment hole
20 Connection component
40S Routing board
40T Routing structure
41S Base plate
41T Base member
42 Bus bar
42h Attachment hole
90 Fastening member
90a First portion
90b Second portion
91 Shaft
92 Base portion
93 Heat storage portion
110 Metal plate (heat dissipation member)
120 Heat transfer member
130 Connection component
133h Attachment hole

1. A fastening member for use in an electrical connection unit, comprising:
a shaft that is inserted into a first attachment hole of a first member and a second attachment hole of a second member in a state in which the first attachment hole and the second attachment hole overlap each other in a first direction and has a screw thread;
a base portion that has a width in a second direction intersecting the first direction larger than a width of the shaft and faces the first member or the second member in the first direction; and
a heat storage portion that is provided on a side opposite to the shaft with respect to the base portion and formed integrally with the base portion.

2. The fastening member according to claim 1, wherein
a width of the heat storage portion in the second direction is larger than a width of the base portion in the second direction.

3. The fastening member according to claim 2, wherein
a thickness of the heat storage portion in the first direction is larger than a thickness of the base portion in the first direction.

4. The fastening member according to claim 2, wherein
the heat storage portion has an outer shape different from a regular circle and a regular polygon when viewed from the first direction.

5. An electrical connection unit comprising:
at least one of the first member and the second member; and
the fastening member according to claim 1.

6. The electrical connection unit according to claim 5, further comprising an insulating base member,
wherein
a width of the heat storage portion in the second direction is larger than a width of the base portion in the second direction, and
the base member includes a holding portion that is located between the first member and the heat storage portion in the first direction, faces the heat storage portion in the first direction, and holds the heat storage portion.

7. The electrical connection unit according to claim 5, further comprising:
a heat dissipation member facing the heat storage portion from a side opposite to the first member and the second member; and
a heat transfer member disposed between the heat storage portion and the heat dissipation member.

8. A fastening member for use in an electrical connection unit, comprising:
a first portion that is inserted into a first attachment hole of a first member and a second attachment hole of a second member in a state in which the first attachment hole and the second attachment hole overlap each other in a first direction, has a screw thread, and is engaged with a nut; and
a second portion that has a width in a second direction intersecting the first direction larger than a width of the first portion, faces the first member or the second member in the first direction, and has a volume twice or more a volume of the nut.

9. An electrical connection unit comprising:
at least one of the first member and the second member; and
the fastening member according to claim 8.

10. An electrical connection unit comprising:
a fastening member including a first portion that is inserted into a first attachment hole of a first member and a second attachment hole of a second member in a state in which the first attachment hole and the second attachment hole overlap each other in a first direction and has a screw thread, and a second portion that has a width in a second direction intersecting the first direction larger than a width of the first portion and faces the first member or the second member in the first direction;
a heat dissipation member that faces the second portion from a side opposite to the first member and the second member; and
a heat transfer member that is disposed between the second portion and the heat dissipation member.
